(19) United States
(12) Patent Application Publication
(10) Pub. No.: US 2025/0349506 A1
(43) Pub. Date: Nov. 13, 2025

(54) CHARGED PARTICLE BEAM WRITING APPARATUS, CHARGED PARTICLE BEAM WRITING METHOD, AND NON-TRANSITORY COMPUTER-READABLE STORAGE MEDIUM STORING PROGRAM

(71) Applicant: NuFlare Technology, Inc., Yokohama-shi (JP)

(72) Inventors: Haruyuki NOMURA, Yokohama-shi (JP); Shingo MORI, Yokohama-shi (JP)

(73) Assignee: NuFlare Technology, Inc., Yokohama-shi (JP)

(21) Appl. No.: 19/202,452

(22) Filed: May 8, 2025

Related U.S. Application Data
(63) Continuation of application No. PCT/JP2024/017293, filed on May 9, 2024.

(51) Int. Cl. H01J 37/302; H01J 37/317

(52) U.S. Cl. CPC H01J 37/3023; H01J 37/3174

(57) ABSTRACT

A charged particle beam writing apparatus, includes: an effective temperature calculation circuit configured to calculate, for each of mesh regions obtained by dividing each stripe region, a representative value of a temperature rise while a beam array region irradiated with multiple beams is passing through a mesh region of interest as a mesh region concerned, among temperature rises due to heat caused by beam irradiations onto the surface of the target object and affecting the mesh region of interest, as an effective temperature of the mesh region of interest; and a modulated dose calculation circuit configured to calculate a modulated dose at each position obtained by correcting a dose at each position defined in the dose map using a function using an effective temperature distribution map defining the effective temperature for each mesh region, an area density map for each position, and a back scattering coefficient for proximity effect correction.

### CROSS-REFERENCE TO RELATED APPLICATION

This application is a continuation application based upon and claims the benefit of priority from International Application PCT/JP2024/017293, the International Filing Date of which is May 9, 2024. The contents described in PCT/JP2024/017293 are incorporated herein by reference.

### BACKGROUND OF THE INVENTION

### Field of the Invention

The present invention relates to a charged particle beam writing apparatus, a charged particle beam writing method, and a non-transitory computer-readable storage medium storing a program, and relates to, for example, a method for correcting resist heating that occurs in charged particle beam writing (or “drawing”).

### Related Art

Lithography technology, which is responsible for the advancement of miniaturization of semiconductor devices, is an extremely important process that is the only pattern generation process among the semiconductor manufacturing processes. In recent years, as LSIs have become more highly integrated, the circuit line width required for semiconductor devices has become smaller year by year. Here, electron beam writing technology is basically excellent in terms of resolution, and accordingly writing is performed on wafers and the like using an electron beam.

For example, there is a writing apparatus using multiple beams. Compared to the case of writing using a single electron beam, using multiple beams allows irradiation using a large amount of beams at a time, resulting in a significant improvement in throughput. In such a writing apparatus based on the multi-beam method, for example, electron beams emitted from an electron emission source pass through a mask having a plurality of holes to form multiple beams, and each of the multiple beams is subjected to blanking control so that each beam that is not blocked is demagnified by an optical system, deflected by a deflector, and emitted to a desired position on a target object.

Here, in the case of writing using electron beams, if an attempt is made to perform irradiation in a short period of time electron beams with higher-density of irradiation energy, there has been a problem that a phenomenon called resist heating occurs in which a temperature of a substrate increased to change the resist sensitivity and accordingly the line width accuracy deteriorates. For example, in single beam writing, a method has been adopted in which the amount of dose correction for the current shot is determined by accumulating the effect of temperature rise in each past shot due to a single beam. However, since a plurality of beams are used in multi-beam writing, the method for accumulating the effect of temperature rise for each past shot and each beam requires a huge amount of calculation. In addition, in multi-beam writing, since a plurality of beams are shot at the same time, it is necessary to consider the effect of temperature rise from a plurality of other beams located in a wide range of region to be irradiated at the same time.

Here, if heating effect correction is performed by dose modulation, the corrected dose will deviate from the correction conditions for the proximity effect correction performed before the heating effect correction. For this reason, there may be problems such as correction residuals in the proximity effect correction. In this regard, a method is disclosed for determining the proximity effect correction coefficient for the dose again, taking into account edge and corner correction due to dose variation, although this is not a heating effect correction (see, for example, Japanese Patent No. 6523767).

### BRIEF SUMMARY OF THE INVENTION

According to one aspect of the present invention, a charged particle beam writing apparatus, includes:
a dose map creation circuit configured to create a dose map defining a dose incident on a position concerned for each of a plurality of positions in each of a plurality of stripe regions obtained by dividing a writing region on a surface of a target object irradiated with a charged particle beam in a first direction;
an effective temperature calculation circuit configured to calculate, for each of a plurality of mesh regions obtained by dividing each stripe region in the first direction and a second direction, corresponding to a stage movement direction, linearly independent of the first direction, a representative value of a temperature rise while a beam array region irradiated with multiple beams is passing through a mesh region of interest as a mesh region concerned, among temperature rises due to heat caused by beam irradiations onto the surface of the target object and affecting the mesh region of interest, as an effective temperature of the mesh region of interest;
a modulated dose calculation circuit configured to calculate a modulated dose at each position obtained by correcting a dose at each position defined in the dose map using a function using an effective temperature distribution map defining the effective temperature for each mesh region, an area density map for each position, and a back scattering coefficient for proximity effect correction; and
a writing mechanism configured to write a pattern on the target object using a charged particle beam with the modulated dose.

According to another aspect of the present invention, a charged particle beam writing method, includes:
creating a dose map defining a dose incident on a position concerned for each of a plurality of positions in each of a plurality of stripe regions obtained by dividing a writing region on a surface of a target object irradiated with a charged particle beam in a first direction;
calculating, for each of a plurality of mesh regions obtained by dividing each stripe region in the first direction and a second direction, corresponding to a stage movement direction, linearly independent of the first direction, a representative value of a temperature rise while a beam array region irradiated with multiple beams is passing through a mesh region of interest as a mesh region concerned, among temperature rises due to heat caused by beam irradiations onto the surface of the target object and affecting the mesh region of interest, as an effective temperature of the mesh region of interest;
calculating a modulated dose at each position obtained by correcting a dose at each position defined in the dose map using a function using an effective temperature distribution map defining the effective temperature for each mesh region, an area density map for each position, and a back scattering coefficient for proximity effect correction; and
writing a pattern on the target object using a charged particle beam with the modulated dose.

According to yet another aspect of the present invention, a non-transitory computer-readable storage medium stores a program for causing a computer to execute processing including:
creating a dose map defining a dose incident on a position concerned for each of a plurality of positions in each of a plurality of stripe regions obtained by dividing a writing region on a target object surface irradiated with a charged particle beam in a first direction;
calculating, for each of a plurality of mesh regions obtained by dividing each stripe region in the first direction and a second direction, corresponding to a stage movement direction, linearly independent of the first direction, a representative value of a temperature rise while a beam array region irradiated with multiple beams is passing through a mesh region of interest as a mesh region concerned, among temperature rises due to heat caused by beam irradiations onto the surface of the target object and affecting the mesh region of interest, as an effective temperature of the mesh region of interest;
storing an effective temperature distribution map defining the effective temperature for each mesh region in a storage device;
reading out the effective temperature distribution map from the storage device and calculating a modulated dose at each position obtained by correcting a dose at each position defined in the dose map using a function using the effective temperature distribution map, an area density map for each position, and a back scattering coefficient for proximity effect correction; and writing a pattern on the target object using a charged particle beam with the modulated dose.

### BRIEF DESCRIPTION OF THE DRAWINGS

FIG. 1 is a conceptual diagram showing the configuration of a writing apparatus according to Embodiment 1;

FIG. 2 is a conceptual diagram showing the configuration of a shaping aperture array substrate in Embodiment 1;

FIG. 3 is a cross-sectional view showing the configuration of a blanking aperture array mechanism in Embodiment 1;

FIG. 4 is a top surface conceptual diagram showing a part of the configuration within a membrane region of the blanking aperture array mechanism in Embodiment 1;

FIG. 5 is a diagram showing an example of an individual blanking mechanism in Embodiment 1;

FIG. 6 is a conceptual diagram for explaining an example of a writing operation in Embodiment 1;

FIG. 7 is a diagram showing an example of a multi-beam irradiation region and a writing target pixel in Embodiment 1;

FIG. 8 is a diagram for explaining an example of a multi-beam writing operation in Embodiment 1;

FIG. 9 is a diagram showing an example of the relationship between temperature and temperature distribution caused by emission of a single beam to a region of one beam pitch in a comparative example of Embodiment 1;

FIG. 10 is a diagram showing an example of the relationship between temperature and temperature distribution caused by simultaneous emission of multiple beams in Embodiment 1;

FIG. 11 is a diagram for explaining an example of proximity effect correction in a state in which there is no resist heating in a comparative example of Embodiment 1;

FIG. 12 is a diagram for explaining the relationship among a pattern area density, a proximity effect-corrected dose, and a resolution threshold value in a comparative example of Embodiment 1;

FIG. 13 is a diagram showing an example of accumulated energy distribution and an example of CD distribution in a state without resist heating and a state with resist heating in Embodiment 1;

FIG. 14 is a diagram showing an example of accumulated energy distribution and an example of CD distribution after heating effect correction in Embodiment 1;

FIG. 15 is a diagram showing an example of the accumulated energy distribution of a pattern after the influence of a heating effect before and after heating effect correction in Embodiment 1;

FIG. 16 is a diagram for explaining an example of a process of deriving a correction term in Embodiment 1;

FIG. 17 is a diagram for explaining another example of the process of deriving a correction term in Embodiment 1;

FIG. 18 is a flowchart showing an example of main steps of a writing method according to Embodiment 1;

FIG. 19 is a block diagram showing an example of the internal configuration of an effective temperature calculation processing unit in Embodiment 1;

FIG. 20 is a diagram showing an example of a processing mesh in Embodiment 1;

FIG. 21 is a diagram for explaining a method for calculating an effective temperature in Embodiment 1;

FIG. 22 is a diagram for explaining a part of the effective temperature calculation equation in Embodiment 1;

FIG. 23 is a diagram for explaining an example of calculation equation for a heat spread function in Embodiment 1;

FIG. 24 is a diagram for explaining another part of the effective temperature calculation equation in Embodiment 1;

FIG. 25 is a diagram for explaining another part of the effective temperature calculation equation in Embodiment 1;

FIG. 26 is a diagram for explaining another part of the effective temperature calculation equation in Embodiment 1;

FIG. 27 is a diagram for explaining an example of a virtual model of effective temperature in Embodiment 1;

FIG. 28 is a diagram for explaining an example of a kernel derivation process in Embodiment 1;

FIG. 29 is a diagram showing another example of the kernel derivation process in Embodiment 1;

FIG. 30 is a diagram showing another example of the kernel derivation process in Embodiment 1;

FIG. 31 is a diagram for explaining the kernel in Embodiment 1;

FIG. 32 is a diagram showing an example of the relationship between the stage speed and the kernel in Embodiment 1;

FIG. 33 is a diagram showing an example of the relationship between the movement direction size of a beam array and the kernel in Embodiment 1;

FIG. 34 is a diagram showing another example of the relationship between the movement direction size of the beam array and the kernel in Embodiment 1;

FIG. 35 is a diagram showing an example of a kernel defined as a table in Embodiment 1;

FIG. 36 is a diagram showing an example of a kernel equation defined as a continuous function in Embodiment 1;

FIG. 37 is a diagram for explaining a method for calculating an effective temperature in Embodiment 1;

FIG. 38 is a diagram showing an example of the relationship between the line width CD and temperature in Embodiment 1;

FIG. 39 is a diagram showing an example of the relationship between the line width CD and the dose in Embodiment 1;

FIG. 40 is a diagram showing an example of accumulated energy distribution and an example of CD distribution after heating effect correction in Embodiment 1;

FIG. 41 is a conceptual diagram showing the configuration of a writing apparatus according to Embodiment 2;

FIG. 42 is a flowchart showing an example of main steps of a writing method according to Embodiment 2;

FIG. 43 is a diagram showing an example of the accumulated energy distribution when performing heating effect correction with the maximum value of the effective temperature variable using the method according to Embodiment 1;

FIG. 44 is a diagram for explaining an example of a process of deriving a correction term in Embodiment 2; and

FIG. 45 is a diagram showing an example of the accumulated energy distribution when performing heating effect correction with the maximum value of the effective temperature variable using the method according to Embodiment 2.

### DETAILED DESCRIPTION OF THE INVENTION

In the following embodiments, an apparatus and a method capable of reducing correction residuals when correcting resist heating in charged particle beam writing are provided.

In addition, in the embodiments, a configuration using an electron beam as an example of a charged particle beam will be described. However, the charged particle beam is not limited to an electron beam, and may be a beam using a charged particle such as an ion beam.

### Embodiment 1

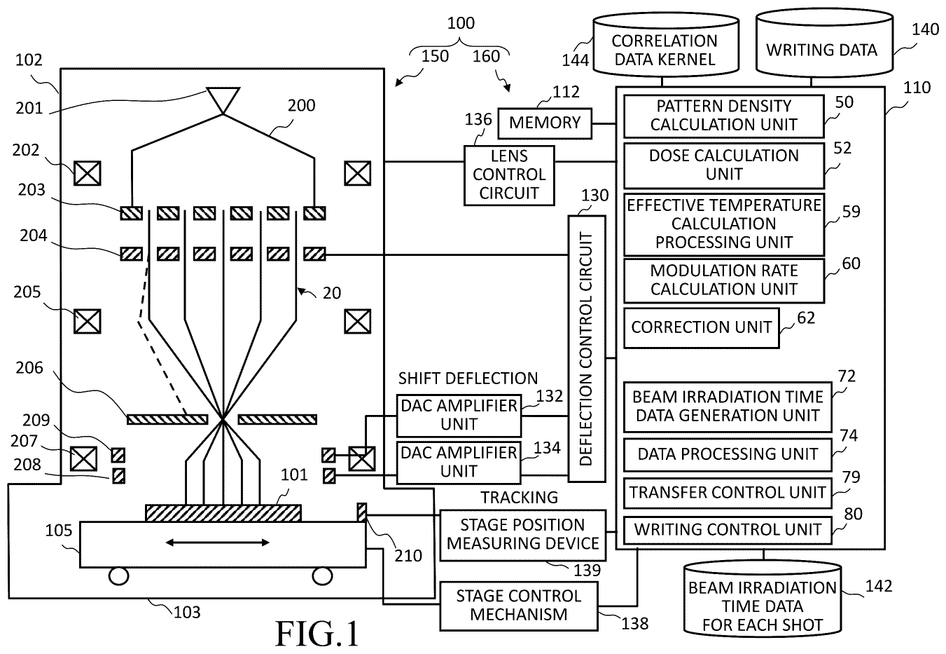

FIG. 1 is a conceptual diagram showing the configuration of a writing apparatus according to Embodiment 1. In FIG. 1, a writing apparatus 100 includes a writing mechanism 150 and a control system circuit 160. The writing apparatus 100 is an example of a multi-charged particle beam writing apparatus and an example of a multi-charged particle beam exposure apparatus. The writing mechanism 150 includes an electron optical column 102 (electron beam column) and a writing chamber 103. An electron emission source 201, an illumination lens 202, a shaping aperture array substrate 203, a blanking aperture array mechanism 204, a demagnifying lens 205, a limiting aperture substrate 206, an objective lens 207, a main deflector 208, and a sub-deflector 209 are arranged inside the electron optical column 102. An XY stage 105 is arranged in the writing chamber 103. On the XY stage 105, a target object 101 such as a mask, which becomes a writing target substrate during writing (during exposure), is arranged. The target object 101 includes an exposure mask used in manufacturing semiconductor devices, a semiconductor substrate (silicon wafer) on which a semiconductor device is manufactured, and the like. In addition, the target object 101 is coated with a resist. The target object 101 includes, for example, a mask blank which is coated with resist and on which nothing has been written yet. A mirror 210 for measuring the position of the XY stage 105 is further arranged on the XY stage 105.

The control system circuit 160 includes a control calculator 110, a memory 112, a deflection control circuit 130, digital-to-analog conversion (DAC) amplifiers 132 and 134, a lens control circuit 136, a stage control mechanism 138, a stage position measuring device 139, and storage devices 140, 142, and 144 such as magnetic disk drives. The control calculator 110, the memory 112, the deflection control circuit 130, the lens control circuit 136, the stage control mechanism 138, the stage position measuring device 139, and the storage devices 140, 142, and 144 are connected to each other through a bus (not shown). The DAC amplifier units 132 and 134 and the blanking aperture array mechanism 204 are connected to the deflection control circuit 130. The sub-deflector 209 is formed by electrodes having four or more poles, and each electrode is controlled by the deflection control circuit 130 through the DAC amplifier unit 132. The main deflector 208 is formed by electrodes having four or more poles, and each electrode is controlled by the deflection control circuit 130 through the DAC amplifier unit 134. The stage position measuring device 139 measures the position of the XY stage 105 using the principle of laser interferometry by receiving the reflected light from the mirror 210.

A pattern density calculation unit 50, a dose calculation unit 52, an effective temperature calculation processing unit 59, a modulation rate calculation unit 60, a correction unit 62, a beam irradiation time data generation unit 72, a data processing unit 74, a transfer control unit 79, and a writing control unit 80 are arranged in the control calculator 110. Each “˜unit”, such as the pattern density calculation unit 50, the dose calculation unit 52, the effective temperature calculation processing unit 59, the modulation rate calculation unit 60, the correction unit 62, the beam irradiation time data generation unit 72, the data processing unit 74, the transfer control unit 79, and the writing control unit 80, has a processing circuit. Examples of such a processing circuit include an electrical circuit, a computer, a processor, a circuit board, a quantum circuit, or a semiconductor device. For each “˜unit”, a common processing circuit (the same processing circuit) may be used or different processing circuits (separate processing circuits) may be used. Information input and output to and from the pattern density calculation unit 50, the dose calculation unit 52, the effective temperature calculation processing unit 59, the modulation rate calculation unit 60, correction unit 62, the beam irradiation time data generation unit 72, the data processing unit 74, transfer control unit 79, and the writing control unit 80 and information being calculated are stored in the memory 112 each time.

The writing operation of the writing apparatus 100 is controlled by the writing control unit 80. In addition, processing for the transfer of beam irradiation time data of each shot to the deflection control circuit 130 is controlled by the transfer control unit 79.

In addition, chip data is input from outside the writing apparatus 100 and stored in the storage device 140. The writing data includes chip data and pattern writing conditions data. In the chip data, for example, a figure code, coordinates, and size are defined for each figure. In addition, the pattern writing conditions data includes information indicating the degree of multiplicity and the stage speed.

In addition, the storage device 144 stores correlation data, which will be described later, for calculating a modulation rate for correcting resist heating.

Here, FIG. 1 describes components necessary for explaining Embodiment 1. The writing apparatus 100 may also include other components that are normally required.

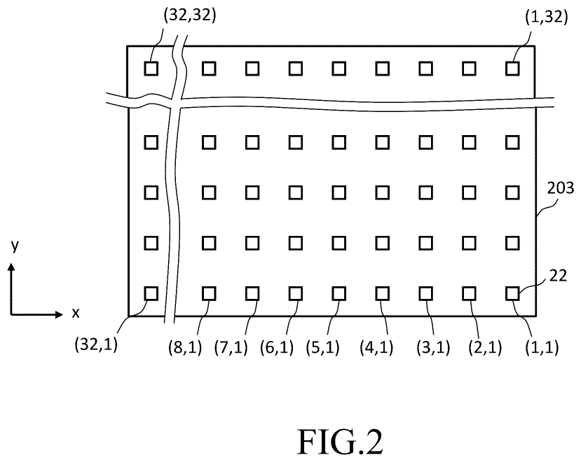

FIG. 2 is a conceptual diagram showing the configuration of a shaping aperture array substrate in Embodiment 1. In FIG. 2, in the shaping aperture array substrate 203, holes (openings) 22 are formed in a matrix of p columns long (in the y direction)×q rows wide (in the x direction) (p, q≥2) at predetermined arrangement pitches. In the example of FIG. 2, for example, a case is shown in which 500 columns×500 rows of holes 22 are formed in the length and width directions (x and y directions). The number of holes 22 is not limited to thereto. The holes 22 are formed in rectangles having the same dimension and shape. Alternatively, the holes 22 may be circles having the same diameter. Some of electron beams 200 pass through the plurality of holes 22 to form multiple beams 20. In other words, the shaping aperture array substrate 203 forms the multiple beams 20.

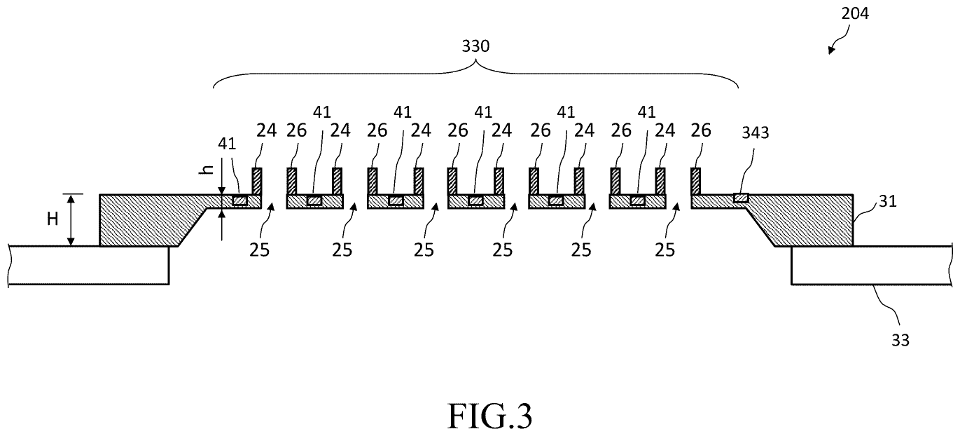

FIG. 3 is a cross-sectional view showing the configuration of a blanking aperture array mechanism in Embodiment 1.

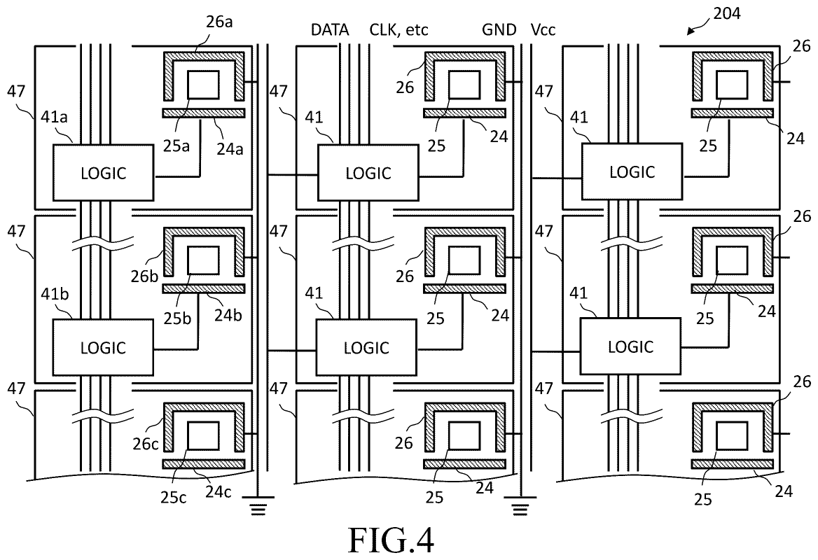

FIG. 4 is a top surface conceptual diagram showing a part of the configuration within the membrane region of the blanking aperture array mechanism in Embodiment 1. In addition, in FIGS. 3 and 4, the positional relationship between a control electrode 24, a counter electrode 26, and a control circuit 41 and a pad 343 is not described in the same manner. In the blanking aperture array mechanism 204, as shown in FIG. 3, a blanking aperture array substrate 31 using a semiconductor substrate formed of silicon or the like is arranged on a support base 33. In a membrane region 330 at the center of the blanking aperture array substrate 31, a through hole 25 (opening) through which each of the multiple beams 20 passes is opened at a position corresponding to each hole 22 of the shaping aperture array substrate 203 shown in FIG. 2. Then, for each of a plurality of through holes 25, a set of the control electrode 24 and the counter electrode 26 (blanker: blanking deflector) are arranged at positions facing each other with the corresponding through hole 25 interposed therebetween. In addition, a control circuit 41 (logic circuit; cell) to apply a deflection voltage to the control electrode 24 for each through hole 25 is arranged inside the blanking aperture array substrate 31 near each through hole 25. The counter electrode 26 for each beam is grounded.

In addition, as shown in FIG. 4, n-bit (for example, 10-bit) parallel wiring lines for control signals are connected to each control circuit 41. In addition to n-bit parallel wiring lines for beam irradiation time control signal (data), wiring lines for a clock signal, a load signal, a shot signal, and a power supply and the like are connected to each control circuit 41. For these wirings lines and the like, some of the parallel wiring lines may be used. For each beam forming the multiple beams 20, an individual blanking mechanism 47 is formed by the control electrode 24, the counter electrode 26, and the control circuit 41. In addition, in Embodiment 1, for example, a shift register method is used as a data transfer method. In the shift register method, the multiple beams 20 are divided into a plurality of groups for each of the plurality of beams, and a plurality of shift registers for a plurality of beams in the same group are connected in series to each other. Specifically, a plurality of control circuits 41 formed in an array in the membrane region 330 are grouped at a predetermined pitch in the same row or column, for example. The control circuits 41 in the same group are connected in series to each other as shown in FIG. 4. Then, the signal from the pad 343 arranged for each group is transmitted to the control circuit 41 in the group.

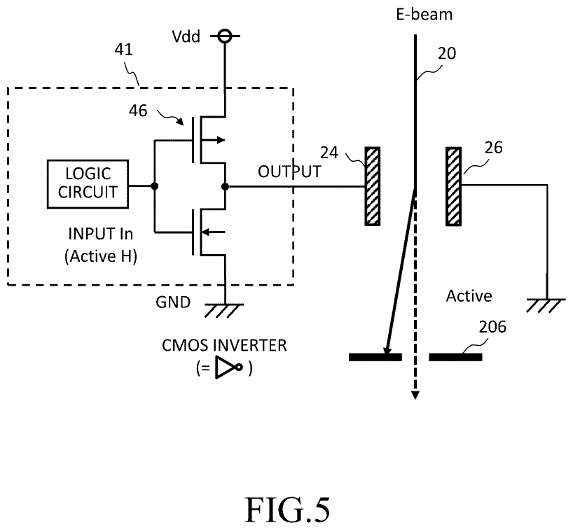

FIG. 5 is a diagram showing an example of an individual blanking mechanism in Embodiment 1. In FIG. 5, an amplifier 46 (an example of a switching circuit) is arranged in the control circuit 41. In the example of FIG. 5, a CMOS (Complementary MOS) inverter circuit serving as a switching circuit is arranged as an example of the amplifier 46. Either an L (low) potential (for example, ground potential) that is lower than the threshold voltage or an H (high) potential (for example, 1.5 V) that is equal to or higher than the threshold voltage is applied to the input (IN) of the CMOS inverter circuit as a control signal. In Embodiment 1, in a state in which the L potential is applied to the input (IN) of the CMOS inverter circuit, the output (OUT) of the CMOS inverter circuit applied to the control circuit 41 has a positive potential (Vdd), and the corresponding beam 20 is deflected by the electric field due to the potential difference from the ground potential of the counter electrode 26 and blocked by the limiting aperture substrate 206. In this manner, the beam is controlled to be turned off. On the other hand, in a state in which the H potential is applied to the input (IN) of the CMOS inverter circuit (active state), the output (OUT) of the CMOS inverter circuit has a ground potential, and there is no potential difference from the ground potential of the counter electrode 26. Therefore, since the corresponding beam 20 is not deflected, the beam passes through the limiting aperture substrate 206. In this manner, the beam is controlled to be turned on. Blanking control is made by such deflection.

Then, each individual blanking mechanism 47 controls the beam irradiation time of the shot individually for each beam using a counter circuit (not shown) in accordance with the beam irradiation time control signal transferred for each beam.

Next, a specific example of the operation of the writing mechanism 150 will be described. An electron beam 200 emitted from the electron emission source 201 (emission source) illuminates the entire shaping aperture array substrate 203 almost vertically through the illumination lens 202. A plurality of rectangular holes 22 (openings) are formed in the shaping aperture array substrate 203, and the electron beam 200 illuminates a region including all of the plurality of holes 22. Some of the electron beams 200 emitted to the positions of the plurality of holes 22 pass through the plurality of holes 22 in the shaping aperture array substrate 203 to form, for example, rectangular multiple beams (a plurality of electron beams) 20. Such multiple beams 20 pass through each corresponding blanker (first deflector: individual blanking mechanism 47) of the blanking aperture array mechanism 204. Each blanker performs blanking control on a beam passing therethrough individually so that the beam is in an ON state during the set writing time (beam irradiation time).

The multiple beams 20 that have passed through the blanking aperture array mechanism 204 are reduced by the demagnifying lens 205 and travel toward a central hole formed in the limiting aperture substrate 206. Here, the electron beam deflected by the blanker of the blanking aperture array mechanism 204 is displaced from the central hole of the limiting aperture substrate 206 and is blocked by the limiting aperture substrate 206. On the other hand, the electron beam that is not deflected by the blanker of the blanking aperture array mechanism 204 passes through the central hole of the limiting aperture substrate 206 as shown in FIG. 1. Thus, the limiting aperture substrate 206 blocks each beam that is deflected by the individual blanking mechanism 47 so as to be in a beam OFF state. Then, by the beam that has passed through the limiting aperture substrate 206 and is formed from the beam ON state to the beam OFF state, each beam for one shot is formed. The multiple beams 20 that have passed through the limiting aperture substrate 206 are focused by the objective lens 207 to become a pattern image having a desired reduction ratio, and all of the multiple beams 20 that have passed through the limiting aperture substrate 206 are collectively deflected in the same direction by the main deflector 208 and the sub-deflector 209 and emitted to each irradiation position on the target object 101 of each beam. In addition, for example, when the XY stage 105 is continuously moving, tracking control is performed by deflecting the multiple beams 20 with the main deflector 208 so that the irradiation position of the beam follows the movement of the XY stage 105. The multiple beams 20 emitted at one time are ideally arranged at a pitch obtained by multiplying the arrangement pitch of the plurality of holes 22 of the shaping aperture array substrate 203 by the desired reduction ratio described above.

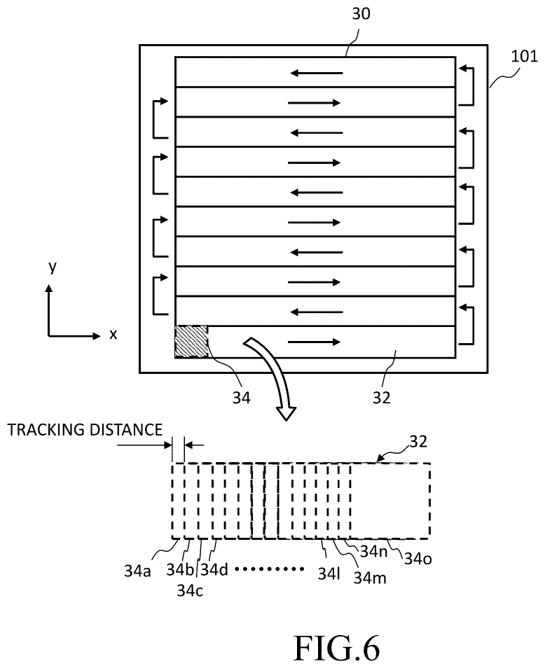

FIG. 6 is a conceptual diagram for explaining an example of the writing operation in Embodiment 1. As shown in FIG. 6, a writing region 30 of the target object 101 is virtually divided into a plurality of rectangular stripe regions 32 with a predetermined width in the y direction, for example. First, the XY stage 105 is moved to make an adjustment so that an irradiation region 34 that can be irradiated with one shot of the multiple beams 20 is located at the left end of the first stripe region 32 or further to the left, and writing is started. When writing the first stripe region 32, the XY stage 105 is moved, for example, in the −x direction, so that the writing proceeds relatively in the x direction. The XY stage 105 is continuously moved, for example, at a constant speed. After the end of the writing in the first stripe region 32, the stage position is moved in the −y direction and then the XY stage 105 is moved, for example, in the x direction, to perform writing in the same manner in the −x direction. This operation is repeated to perform writing in each stripe region 32 in order. The writing time can be reduced by performing writing while alternately changing the direction. However, writing may proceed in the same direction when writing each stripe region 32, without being limited to the case of performing writing while alternately changing the direction. When moving the XY stage 105 at a constant speed, the continuous movement speed may be different for each stripe. In one shot, by multiple beams formed by passing through each hole 22 of the shaping aperture array substrate 203, a plurality of shot patterns, up to the same number as each hole 22, are formed at a time.

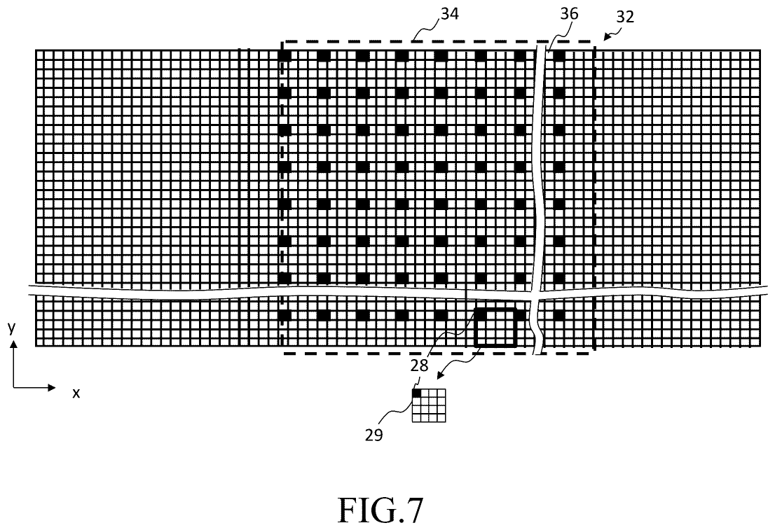

FIG. 7 is a diagram showing an example of a multi-beam irradiation region and a writing target pixel in Embodiment 1. In FIG. 7, the stripe region 32 is divided into a plurality of mesh regions with the beam size of the multiple beams 20 and a mesh shape, for example. Each of such mesh regions is a writing target pixel 36 (unit irradiation region, irradiation position, or writing position). The size of the writing target pixel 36 is not limited to the beam size, and may be any size regardless of the beam size. For example, the size of the writing target pixel 36 may be 1/a (a is an integer of 1 or more) of the beam size. The example in FIG. 7 shows a case where the writing region 30 of the target object 101 is divided into a plurality of stripe regions 32, for example, in the y direction, with substantially the same width as the size of the irradiation region 34 (beam array region) that can be irradiated with one-time multiple beams 20. The size of the rectangular irradiation region 34 in the x direction can be defined as the number of beams in the x direction x the pitch between beams in the x direction. The size of the rectangular irradiation region 34 in the y direction can be defined as the number of beams in the y direction x the pitch between beams in the y direction. In the example of FIG. 7, for example, 500 rows×500 columns of multiple beams are abbreviated to 8 rows×8 columns of multiple beams. Then, in the irradiation region 34, a plurality of pixels 28 (beam writing positions) that can be irradiated with one shot of the multiple beams 20 are shown. The pitch between the pixels 28 adjacent to each other on the target object surface is the pitch between the multiple beams 20. A rectangular region surrounded with the size of the beam pitch in the x and y directions is one sub-irradiation region 29 (pitch cell). One pixel 28 is included in each sub-irradiation region 29. In the example of FIG. 7, for example, a pixel in the upper left corner of each sub-irradiation region 29 is shown as the pixel 28, which is the writing position of the beam. Each sub-irradiation region 29 is formed by, for example, 10×10 pixels. In the example of FIG. 7, each sub-irradiation region 29 of, for example 10×10 pixels, is abbreviated to, for example, 4×4 pixels.

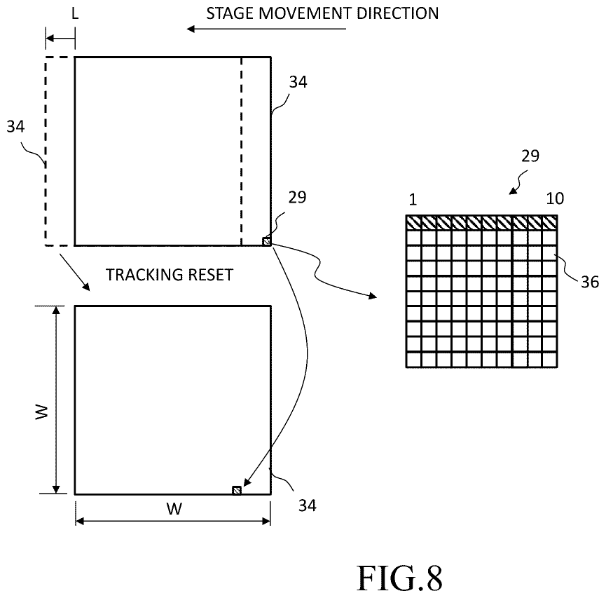

FIG. 8 is a diagram for explaining an example of a multi-beam writing operation in Embodiment 1. The example in FIG. 8 shows a case where each sub-irradiation region 29 on the surface of the target object 101 is written with 10 different beams. In addition, the example in FIG. 8 shows a writing operation in which the XY stage 105 moves continuously at a speed for movement by a distance L of 25 beam pitches, for example, while writing a 1/10 (1/the number of beams used for irradiation) region in each sub-irradiation region 29. In the writing operation shown in the example of FIG. 8, for example, ten different pixels in the same sub-irradiation region 29 are written (exposed) by performing ten shots of the multiple beams 20 with a shot cycle time t_{trk-cycle} while shifting the irradiation position (pixel 36) sequentially by the sub-deflector 209 during the movement of the XY stage 105 by the distance L of 25 beam pitches. The irradiation region 34 is caused to follow the movement of the XY stage 105 by collectively deflecting all of the multiple beams 20 with the main deflector 208, so that the relative position of the irradiation region 34 with respect to the target object 101 does not shift due to the movement of the XY stage 105, while writing (exposing) the ten pixels. In other words, tracking control is performed. Therefore, the distance L deflected collectively by the main deflector 208 during one tracking control is the tracking distance.

When one tracking cycle ends, the tracking is reset to return to the previous tracking start position. In addition, since the writing of the first pixel row from the top of each sub-irradiation region 29 has been completed, in the next tracking cycle after tracking reset, the sub-deflector 209 first performs deflection to match (shift) the writing position of the beam so as to write, for example, a second-row pixel string from the top that has not yet been written in each sub-irradiation region 29. In this manner, a next pixel string to be written changes each time the tracking is reset. During the ten tracking control operations, each pixel 36 in each sub-irradiation region 29 is written once. By repeating this operation while writing the stripe region 32, the position of the irradiation region 34 moves sequentially to irradiation regions 34a to 34o as shown in FIG. 6, and accordingly, the stripe region 32 is written.

In the example of FIG. 8, the sub-irradiation region 29 on the surface of the target object located at the lower right corner of the irradiation region 34 with a width W is at a position that has been moved by a distance L to the left from the lower right corner of the irradiation region 34 during the second tracking control. Therefore, the sub-irradiation region 29 located in the lower right corner of the irradiation region 34 in the first tracking control is written by another beam at a position the distance L away from the lower right corner of the irradiation region 34 to the left in the second tracking control. Here, writing is performed by the beam, for example, 25 beams away from the beam in the lower right corner in the −x direction.

For example, in a writing process set to the multiplicity of 2 per stage pass, each pixel 36 in each sub-irradiation region 29 can be written twice by 20 tracking controls.

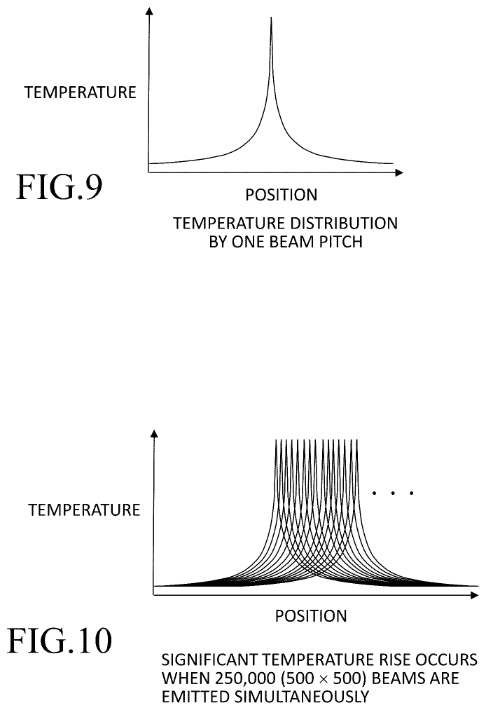

FIG. 9 is a diagram showing an example of the relationship between temperature and temperature distribution caused by emission of a single beam to a region of one beam pitch in a comparative example of Embodiment 1. In FIG. 9, the vertical axis indicate temperature and the horizontal axis indicates temperature distribution. As shown in FIG. 9, the temperature distribution caused by a single beam irradiation has a wide base region. Therefore, there is an influence over a wide range. However, as for the influence on the base region, the temperature rise due to a single beam is at most 0.01° C. or less.

FIG. 10 is a diagram showing an example of the relationship between temperature and temperature distribution caused by simultaneous emission of multiple beams in Embodiment 1. In FIG. 10, the vertical axis indicate temperature and the horizontal axis indicates temperature distribution. The temperature rise due to a single beam is at most 0.01° C. or less. However, for example, if 500×500=250,000 beams are emitted simultaneously, the temperature rises due to respective beams overlap in the base region as shown in FIG. 10. As a result, for example, if 500×500=250,000 beams are emitted simultaneously, there will be a significant temperature rise in the base region.

Techniques for predicting and correcting the heating effect in single-beam writing using a single beam are known. However, there was no precedent for correcting the heating effect in a multi-beam writing method in which a plurality of (for example, 250,000) beams are shot simultaneously multiple times per stage pass. Calculating the heat generated by each of, for example, 250,000 beams in the same manner as for a single beam is not realistic due to the volume of calculations.

In the case of multiple beams, a current density J is extremely small compared to, for example, a single beam using the VSB method, and accordingly the temperature rises slowly. Then, during that time, the temperature distribution due to one shot spreads over several tens of microns. Therefore, even if the shot data and dose data within a stripe are divided and calculated together to some extent, sufficient accuracy can be obtained. In addition, as described above, in multi-beam writing, the position is determined by time because a raster scan method is used. Therefore, if the dose data and the writing speed (stage speed or tracking cycle time) are determined, the temperature rise is determined. This makes it possible to make correction simpler than the writing using the VSB method, which requires both position and time.

Therefore, in Embodiment 1, the dose information of the stripe region 32 is divided into certain Nx×Ny pieces of pixel information including a mesh of interest for which the temperature is to be calculated. A temperature rise at the time of each of a plurality of beam irradiations is calculated for the mesh of interest. Then, a statistical value (for example, an average value) of such a temperature rise is used as the effective temperature (effective temperature T) for heating effect correction. Hereinafter, a specific explanation will be given.

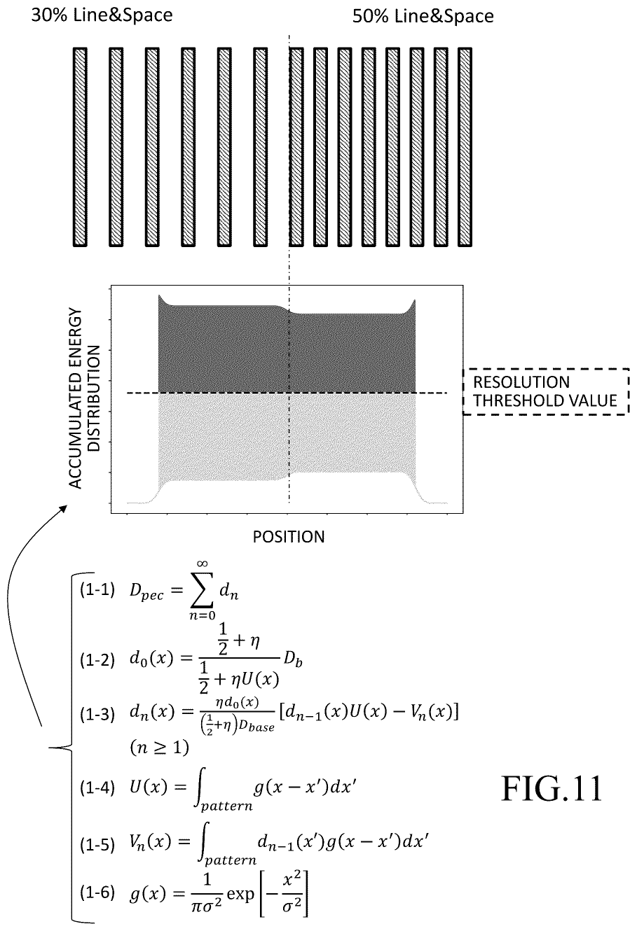

FIG. 11 is a diagram for explaining an example of proximity effect correction in a state in which there is no resist heating in a comparative example of Embodiment 1. FIG. 11 shows a case where a line and space pattern with an area density of 30% and a line and space pattern with an area density of 50% are written. A proximity effect-corrected dose Dpec can be defined by Equations (1-1) to (1-3) using a function dn(x), proximity effect densities U(x) and V(x), a distribution function g(x), and a base doses of the beam Db. In addition, the proximity effect density U(x) is defined by Equation (1-4). Equation (1-4) shows a convolution integral between a pattern area density ρ′(x) and the distribution function g(x) in the proximity mesh. The proximity effect density V(x) is defined by Equation (1-5). An example of the distribution function g(x) is defined by Equation (1-6).

The example in FIG. 11 shows a graph of accumulated energy distribution after proximity effect correction for a line and space pattern with an area density of 30% and a line and space pattern with an area density of 50%. The vertical axis indicates accumulated energy. The horizontal axis indicates a position in the x direction. In the accumulated energy distribution, the sum of energy ηUDpec due to back scattering, which is defined using the proximity effect-corrected dose Dpec and a back scattering coefficient η, is shown.

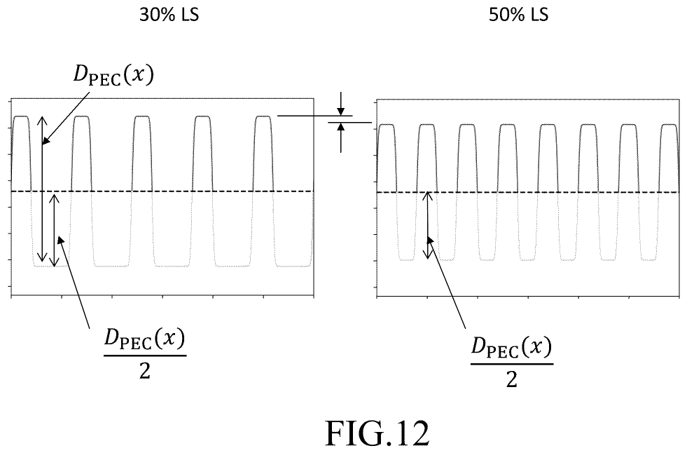

FIG. 12 is a diagram for explaining the relationship among the pattern area density, the proximity effect-corrected dose, and a resolution threshold value in a comparative example of Embodiment 1. In the proximity effect correction, an ISO-FOCAL level, which is the inflection point of the energy distribution and for which the line width CD does not change even if the blur changes, is modeled to be the resolution threshold value. The ISO-FOCAL level, in an ideal state without resist heating, is the dose of a level obtained by adding the accumulated energy ηUDpec due to back scattering to ½ of the proximity effect-corrected dose Dpec. The proximity effect-corrected dose Dpec depends on the pattern area density. Therefore, as shown in FIG. 12, there is a difference in the proximity effect-corrected dose Dpec between the line and space pattern with an area density of 30% and a line and space pattern with an area density of 50%. The proximity effect-corrected dose Dpec for the line and space pattern with a low pattern area density of 30% is larger than the proximity effect-corrected dose Dpec for the line and space pattern with an area density of 50%.

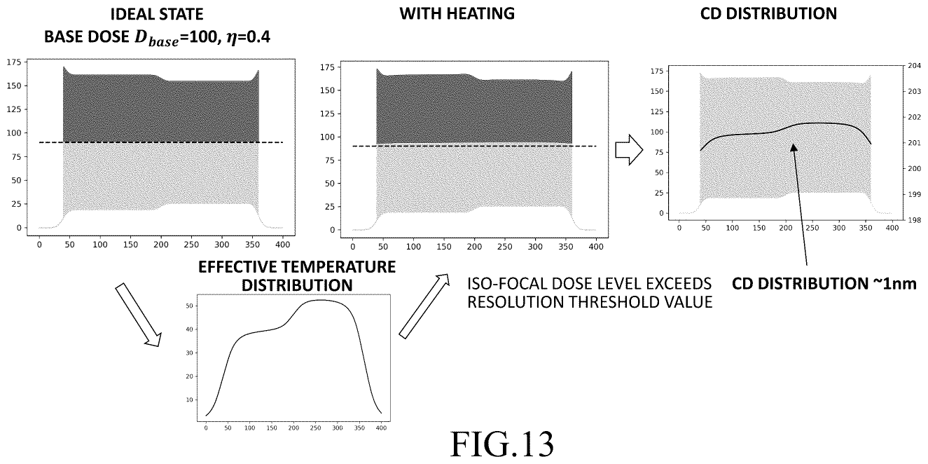

FIG. 13 is a diagram showing an example of accumulated energy distribution and an example of CD distribution in a state without resist heating and a state with resist heating in Embodiment 1. In the accumulated energy distribution shown in FIG. 13, portions above and below the ISO-FOCAL dose level are shown in different colors. Therefore, the boundary between the two colors indicates the ISO-FOCAL dose level. In the accumulated energy distribution where dose modulation is performed by proximity effect correction in an ideal state without resist heating, as shown in FIG. 13, the dose of the level obtained by adding the accumulated energy ηUDpec due to back scattering to ½ of the proximity effect-corrected dose Dpec is a resolution threshold value Dth. In practice, however, for example, resist heating (heating effect) occurs due to the effective temperature T(x) defined in the effective temperature distribution shown in FIG. 13. Specifically, due to the heating effect, the accumulated energy is increased by αT(x)Dpec, which is a product obtained by multiplying a modulation rate α by the effective temperature T(x) and the proximity effect-corrected dose Dpec. For this reason, as shown in the distribution with heating in FIG. 13, the ISO-FOCAL dose level exceeds the resolution threshold value. Therefore, as shown in the CD distribution, the line width (CD) of the pattern changes in proportion to the increase in accumulated energy. In other words, the dose for pattern formation becomes (1+αT(x)) times the expected dose (1+αT(x))Dpec, and the CD distribution becomes non-uniform.

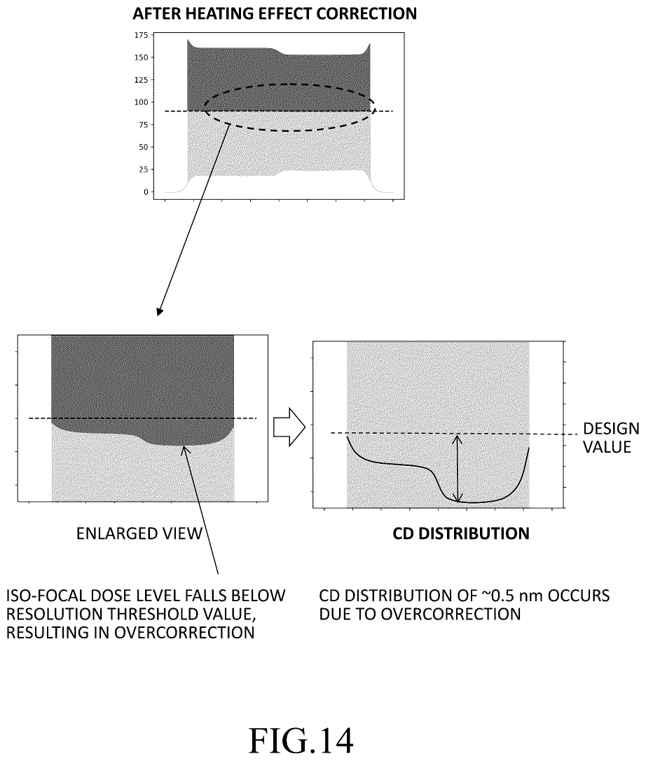

FIG. 14 is a diagram showing an example of accumulated energy distribution and an example of CD distribution after heating effect correction in Embodiment 1. In the accumulated energy distribution shown in FIG. 14, portions above and below the ISO-FOCAL dose level are shown in different colors. Therefore, the boundary between the two colors indicates the ISO-FOCAL dose level. As described above, due to the heating effect, the accumulated energy is increased by αT(x)Dpec. For this reason, in the heating effect correction, the amount of increase in accumulated energy is subtracted from the dose before the correction. In other words, the heating effect can be corrected by setting a heating effect-corrected dose Dtec=(1−αT(x))Dpec.

However, the accumulated energy distribution after the heating effect correction is overcorrected because the ISO-FOCAL dose level is below the resolution threshold value, as shown in FIG. 14. Therefore, as shown in the CD distribution, the line width CD of the pattern deviates from the design value by the amount of overcorrection.

The cause of the CD deviation shown in the CD distribution is the deviation from the proximity effect correction conditions before the heating effect correction due to dose modulation caused by the heating effect correction. In addition, there is a difference between the effective temperature used for the heating effect correction and the actual effective temperature during beam irradiation after the correction.

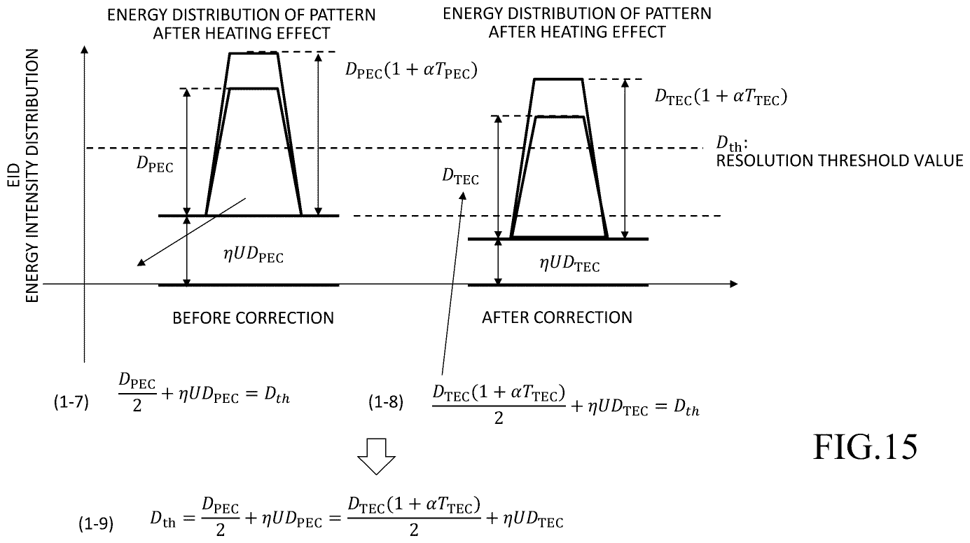

FIG. 15 is a diagram showing an example of the accumulated energy distribution of a pattern after the influence of a heating effect before and after heating effect correction in Embodiment 1. As shown in Equation (1-7) in FIG. 15, before the heating effect correction, a level obtained by adding the accumulated energy ηUDpec due to back scattering to ½ of the proximity effect-corrected dose Dpec is the resolution threshold value Dth. When the heating effect is applied to such a state, the accumulated energy of the pattern after the heating effect is applied can be approximated as Dpec(1+αTpec) using an effective temperature Tpec calculated before the heating effect correction.

On the other hand, the dose due to the heating effect correction is the heating effect-corrected dose Dtec. Since the heating effect-corrected dose Dtec is smaller than the proximity effect-corrected dose Dpec, the level obtained by adding the accumulated energy ηUDtec due to back scattering to ½ of the heating effect-corrected dose Dtec is smaller than the resolution threshold value Dth. In addition, when the heating effect is applied to such a state, the actual accumulated energy can be approximated as Dtec(1+αTtec) using an effective temperature Ttec calculated after the heating effect correction. Therefore, in order to satisfy the proximity effect correction conditions after the heating effect, as shown in Equation (1-8), the level obtained by adding the accumulated energy ηUDtec due to back scattering to ½ of Dtec(1+αTtec) needs to be equal to the resolution threshold value Dth. Therefore, it is preferable to correct the dose so that Equation (1-9) is satisfied in which the value obtained by adding the accumulated energy ηUDtec due to back scattering to ½ of Dtec(1+αTtec) is equal to the value obtained by adding the accumulated energy ηUDpec due to back scattering to ½ of the proximity effect-corrected dose Dpec.

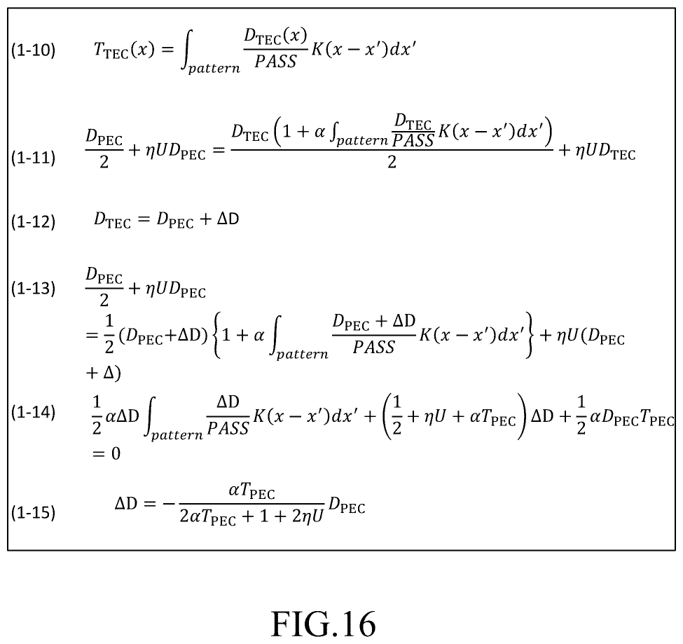

FIG. 16 is a diagram for explaining an example of a process of deriving a correction term in Embodiment 1.

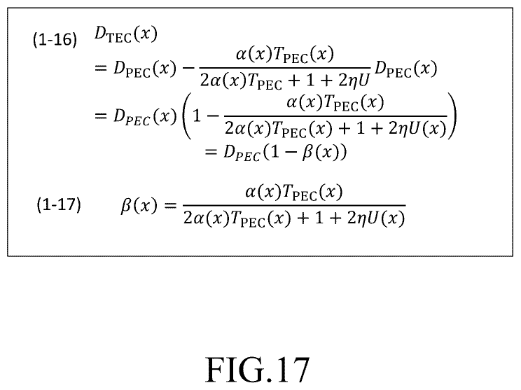

FIG. 17 is a diagram for explaining another example of the process of deriving a correction term in Embodiment 1. The effective temperature Ttec can be defined by Equation (1-10) that uses kernel K(x), which will be described later, for convolution between the kernel K(x) and Dtec(x)/PASS. Here, as a dose per writing process (one pass) when performing multiple writing, a value obtained by dividing Dtec by the number of passes is used. Therefore, Equation (1-9) can be converted into Equation (1-11).

Here, as shown in Equation (1-12), a difference ΔD between Dtec and Dpec is defined. By substituting Equation (1-12) into Equation (1-11), Equation (1-11) can be converted into Equation (1-13). Here, the difference ΔD is small, and furthermore, due to the characteristics of the heating effect in multiple beams, the change is also small within the range of integration and is accordingly negligibly approximated and removed from the integration. Thereafter, by rearranging Equation (1-13) for ΔD, Equation (1-13) can be converted into Equation (1-14).

Assuming that the difference ΔD is small and the first term of ΔD² in Equation (1-14) is ignored, the difference ΔD can be defined by Equation (1-15). By substituting the calculated ΔD into Equation (1-12) for conversion, Dtec can be converted into Equation (1-16). In addition, a function β(x), which is a correction term, is defined using the effective temperature Tpec(x), the proximity density U(x), the back scattering coefficient r, and the modulation rate α(x). The function β(x) can be defined by Equation (1-17).

By performing writing with a beam of the heating effect-corrected dose Dtec(x), which is obtained by correcting the proximity effect-corrected dose Dpec(x), using the function β(x), it is possible to eliminate or reduce the correction residuals of the pattern line width CD due to heating effect correction. Hereinafter, a writing method that uses the function β(x) to perform correction will be described.

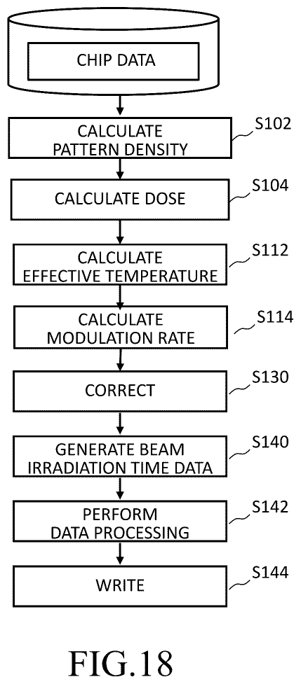

FIG. 18 is a flowchart showing an example of main steps of a writing method according to Embodiment 1. In FIG. 18, in the writing method according to Embodiment 1 a series of steps including a pattern density calculation step (S102), a dose calculation step (S104), an effective temperature calculation step (S112), a modulation rate calculation step (S114), a correction step (S130), a beam irradiation time data generation step (S140), a data processing step (S142), and a writing step (S144) are executed.

First, for each stripe region 32, writing data is read out from the storage device 140.

In the pattern density calculation step (S102), the pattern density calculation unit 50 calculates a pattern density ρ (a pattern area density) for each pixel 36 in the target stripe region 32. The pattern density calculation unit 50 creates a pattern density map for each stripe region 32 using the calculated pattern density ρ of each pixel 36. The pattern density of each pixel 36 is defined as each element of the pattern density map. The created pattern density map is stored in the storage device 144.

In the dose calculation step (S104), the dose calculation unit 52 (an example of a dose map creation circuit) creates a dose map in which the dose incident on each pixel 36 is defined for each pixel 36 of the plurality of pixels 36 (positions) in each of the plurality of stripe regions 32. As each dose defined in the dose map, a proximity effect-corrected dose is used. Each stripe region 32 indicates one stripe region 32 of a plurality of stripe regions 32 obtained by dividing a writing region on the surface of the target object 101 irradiated with the multiple beams 20 in the y direction, for example, by the size in the y direction (first direction) of the beam array region of the multiple beams 20 on the surface of the target object 101. Specifically, the operation is as follows. The dose calculation unit 52 calculates, for each pixel 36, a dose (exposure intensity) for irradiating each pixel 36. Here, it is preferable to calculate the dose as a value obtained by multiplying the proximity effect-corrected dose Dpec for each proximity mesh by the pattern density ρ for each pixel 36. For the proximity effect-corrected dose Dpec for each proximity mesh, the writing region (here, for example, the stripe region 32) is virtually divided into a plurality of proximity mesh regions (mesh regions for calculating proximity effect correction) in a mesh shape of a predetermined size. The size of the proximity mesh region is preferably set to about 1/10 of the influence range of the proximity effect, for example, about 1 μm. Then, writing data is read out from the storage device 140, and for each proximity mesh region, a pattern area density ρ′ of the pattern to be arranged within the proximity mesh region is calculated.

Then, the proximity effect-corrected dose Dpec for correcting the proximity effect is calculated for each proximity mesh region. Here, the size of the mesh region for calculating the proximity effect-corrected dose Dpec does not need to be the same as the size of the mesh region for calculating the pattern area density ρ′. In addition, the correction model and the calculation method for the proximity effect-corrected dose Dpec may be the same as the method used in the conventional single-beam writing method. For example, the above Equations (1-1) to (1-6) may be used for the calculation.

Then, the dose calculation unit 52 creates a dose map (1) for each stripe region 32 using the calculated proximity effect-corrected dose Dpec(x) of each pixel 36. The proximity effect-corrected dose Dpec(x) of each pixel 36 is defined as a value obtained by multiplying the proximity effect-corrected dose Dpec for each proximity mesh by the pattern density ρ for each pixel 36. The proximity effect-corrected dose Dpec(x) for each pixel 36 may be calculated as a relative value to the base doses of the beam Db, which is standardized assuming that the base doses of the beam Db is 1. The created dose map (1) is stored in the storage device 144.

In the effective temperature calculation step (S112), the effective temperature calculation processing unit 59 (effective temperature calculation processing circuit) calculates, for each of a plurality of processing meshes (mesh regions) obtained by dividing each stripe region 32 in the y direction (first direction) and the x direction (second direction) corresponding to the stage movement direction linearly independent of the y direction, a representative value of the temperature rise due to heat that is caused by beam irradiation onto the surface of the target object 101 and affects a mesh region of interest, which is the processing mesh, as an effective temperature of the mesh region of interest. In other words, for each of the plurality of processing meshes (mesh regions) obtained by dividing each stripe region 32 in the x and y directions, the effective temperature calculation processing unit 59 (effective temperature calculation processing circuit) calculates, as the effective temperature of the mesh region of interest, a representative value of the temperature rise due to heat that is caused by beam irradiation to a processing region with the same size as a beam array region overlapping the beam array region on the surface of the target object 101 and affects a mesh region of interest, which is the processing mesh, as an effective temperature of the mesh region of interest. Here, the effective temperature Tpec before correcting the heating effect is calculated. In addition, the x direction (second direction) is a direction parallel to the movement direction of the stage 105 along each stripe region 32. Hereinafter, a method for calculating the effective temperature will be specifically described.

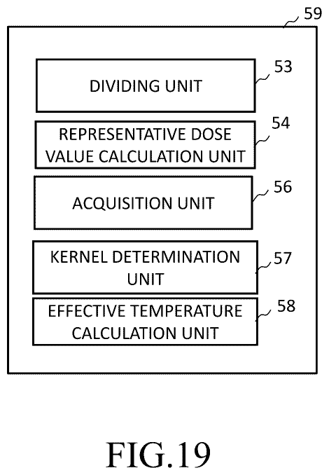

FIG. 19 is a block diagram showing an example of the internal configuration of an effective temperature calculation processing unit in Embodiment 1. In FIG. 19, a dividing unit 53, a representative dose value calculation unit 54, an acquisition unit 56, a kernel determination unit 57, and an effective temperature calculation unit 58 are arranged in the effective temperature calculation processing unit 59.

Each “˜unit”, such as the pattern density calculation unit 50, the dose calculation unit 52, the effective temperature calculation processing unit 59 (the division unit 53, the representative dose value calculation unit 54, the acquisition unit 56, the kernel determination unit 57, and the effective temperature calculation unit 58), the modulation rate calculation unit 60, the correction unit 62, the beam irradiation time data generation unit 72, the data processing unit 74, the transfer control unit 79, and the writing control unit 80 has a processing circuit. Examples of such a processing circuit include an electrical circuit, a computer, a processor, a circuit board, a quantum circuit, or a semiconductor device. For each “˜unit”, a common processing circuit (the same processing circuit) may be used or different processing circuits (separate processing circuits) may be used. Information input and output to and from the pattern density calculation unit 50, the dose calculation unit 52, the effective temperature calculation processing unit 59 (the division unit 53, the representative dose value calculation unit 54, the acquisition unit 56, the kernel determination unit 57, and the effective temperature calculation unit 58), the modulation rate calculation unit 60, the correction unit 62, the beam irradiation time data generation unit 72, the data processing unit 74, the transfer control unit 79, and the writing control unit 80 and information being calculated are stored in the memory 112 each time.

The dividing unit 53 divides each stripe region of a plurality of stripe regions, which are obtained by dividing the writing region of the target object in the y direction with the size in the y direction (first direction) of the beam array region of multiple charged particle beams on the target object surface, into a plurality of mesh regions in the y direction and the x direction (second direction) parallel to the stage movement direction (−x direction) along each stripe region. Specifically, the dividing unit 53 (division processing circuit) divides each stripe region 32 into a plurality of processing meshes (mesh regions) each having a size of 1/Ny of the size W of the beam array region in the y direction (first direction) and a size of 1/Nx of the size W of the beam array region in the x direction (second direction) perpendicular to the y direction (Nx and Ny are both integers of 2 or more), for example.

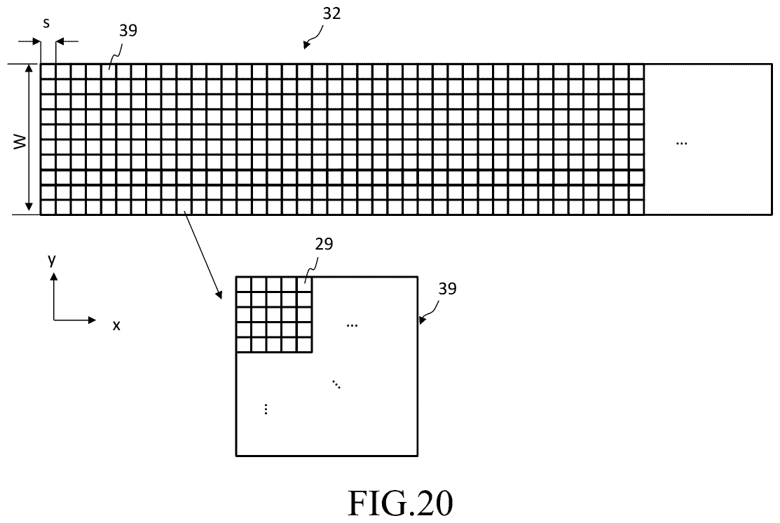

FIG. 20 is a diagram showing an example of a processing mesh in Embodiment 1. As described above, the writing region 30 of the target object 101 is divided into a plurality of stripe regions 32, for example, in the y direction, with the size W of the irradiation region 34 (beam array region) of the multiple beams 20 on the surface of the target object 101. Then, each stripe region 32 is divided into a plurality of processing meshes (mesh regions) 39 each having a size of 1/Ny (Ny is an integer of 2 or more) of the size W of the irradiation region 34 (beam array region) in the y direction and a size of 1/Nx (Nx is an integer of 2 or more) of the size W of the irradiation region 34 (beam array region) in the x direction. The size sx in the x direction and the size sy in the y direction of each processing mesh 39 are set to be larger than the sub-irradiation region 29 with a beam pitch size. In the example of FIG. 12, the size sx in the x direction and the size sy in the y direction of each processing mesh 39 are shown as the same size s.

In Embodiment 1, the size s of the processing mesh 39 is preferably set to, for example, a tracking distance L. The tracking distance L is k times (k is a natural number) the pitch size between the beams on the surface of the target object 101. In the above example, the tracking distance L is set to, for example, 25 times the pitch size between the beams. Therefore, it is preferable that the size s of the processing mesh 39 is set to, for example, a size of 25 beam pitches. Thus, the size s of the processing mesh 39 is larger than the pitch size between the beams on the surface of the target object 101. In addition, the processing mesh 39 is large enough for the pixel 36, which is a unit region to be irradiated with each beam.

Then, the representative dose value calculation unit 54 calculates, for each divided processing mesh 39, a representative value of a plurality of doses due to the multiple beams emitted to the processing mesh 39 as a representative dose value Dij. The processing mesh 39 includes a plurality of sub-irradiation regions 29. As described above, each sub-irradiation region 29 is irradiated with a plurality of different beams. In the above example, for example, each sub-irradiation region 29 is irradiated with ten different beams spaced from each other by 25 beam pitches in the x direction. In addition, a plurality of pixels 36 are included in the processing mesh 39. Here, the representative value of the dose (representative dose value Dij) defined for all pixels 36 in the processing mesh 39 is calculated. Examples of the representative value include an average value, a maximum value, a minimum value, or a median value. Here, for example, an average dose that is an average value is calculated as the representative dose value Dij. The representative dose value calculation unit 54 creates a representative dose value map using the calculated representative dose value Dij of each processing mesh 39. The dose of each processing mesh 39 is defined as each element of the representative dose value map. i indicates an index in the x direction of the processing mesh 39. j indicates an index in the y direction of the processing mesh 39. The created representative dose value map is stored in the storage device 144.

A process is performed to calculate a temperature rise due to heat that is caused by beam irradiation to each processing mesh 39 in the processing region corresponding to the beam array region and affects a mesh region of interest, which is one of the plurality of processing meshes 39. This calculation process is performed by convolution processing using a representative dose value for each processing mesh 39 and a heat spread function that represents the heat spread created by the processing mesh 39.

A repetitive process is performed in which the above-described calculation process is repeated while shifting the position of the processing region corresponding to the beam array region in the x direction on the stripe region, and the representative value of a plurality of temperature rises obtained by performing the repetitive process multiple times until the processing mesh 39 reaches the position of the other end from one end in the x direction of the processing region is calculated as the effective temperature of the mesh region of interest. Specifically, for each processing mesh 39, the effective temperature is calculated using the representative dose value Dij for each processing mesh 39 and a heat spread function PSF that represents the heat spread created by each mesh. The heat spread function PSF can be defined as a general heat diffusion equation by the following Equation (1-18), for example.

$$\frac{\partial T}{\partial t} = λ ( \frac{{\partial }^{2} T}{\partial {x}^{2}} + \frac{{\partial }^{2} T}{\partial {y}^{2}} + \frac{{\partial }^{2} T}{\partial {z}^{2}} ) \qquad ( 1 - 18 )$$

It is possible to use a function that represents the surface temperature of the quartz glass substrate obtained from Equation (1-18). Here, X indicates the thermal diffusivity of a material through which the temperature is diffused. An example of the solution of the above equation will be described later as an explanation of Equation (3-1).

Using the representative dose value Dij and the heat spread function PSF, a convolution process for calculating a temperature rise due to heat that is caused by beam irradiation to each processing mesh 39 in the processing region, which is a rectangular region with the same size as a beam array region formed by, for example, Nx×Ny processing meshes 39, and that affects a mesh region of interest is performed while shifting the position of the rectangular region in the x direction by the size s of the processing mesh 39 on the target stripe region 32 until the mesh region of interest is included in the rectangular region. This process is performed N times from when the mesh region of interest reaches one end position of the rectangular region in the x direction to when the mesh region of interest reaches the other end position. Then, the statistical value of the results of the N convolution processes is calculated as an effective temperature T(k, l).

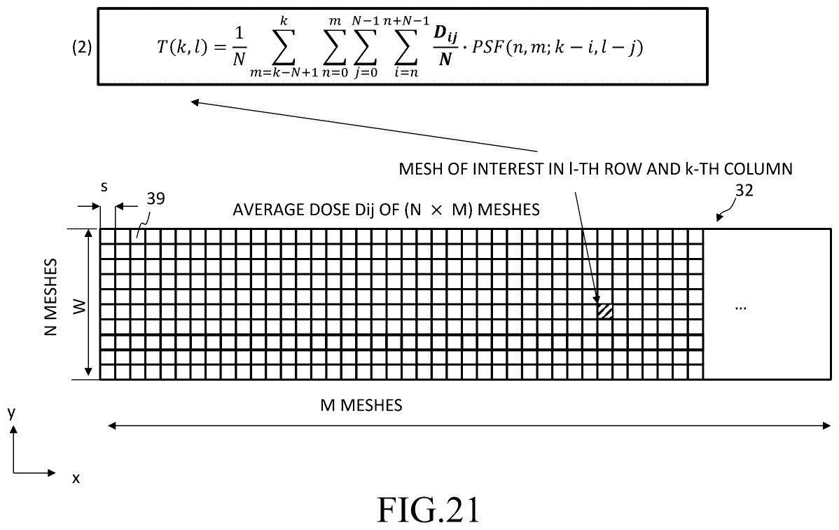

FIG. 21 is a diagram for explaining a method for calculating an effective temperature in Embodiment 1. The effective temperature T(k, l) can be defined by Equation (2) shown in FIG. 21. In the stripe region 32, M processing meshes 39 are arranged in the x direction and N processing meshes 39 are arranged in the y direction. In Equation (2), among the plurality of processing meshes 39 in the stripe region 32, the processing mesh 39 in the 1-th row in the y direction and the k-th column in the x direction is shown as a mesh region of interest.

In Equation (2), i indicates an index in the x direction of the dose statistics map. This is defined as an x-direction index i=0 of the processing mesh 39 at the left end of the stripe region 32.
j indicates a y-direction index of the dose statistics map. This is defined as a y-direction index j=0 of the processing mesh 39 at the bottom of the stripe region 32.
N indicates the number of meshes in the length direction (y direction) of the input dose map used for the effective temperature calculation.
M indicates the number of meshes in the width direction (x direction) of the input dose map used for the effective temperature calculation.
(k, l) indicates an index (reference number) of a processing mesh (mesh region of interest) for which the effective temperature T is calculated among (M×N) processing meshes.
Dij indicates the representative dose value of the processing mesh 39 assigned to index (k, l) in the representative dose value map (μC/cm\hat{ }2).
m indicates the number of beam irradiation from l−N+1 to 1 that is performed until the beam array region (N×N, where Nx=Ny=N) passes through the mesh of interest (k, l). When the processing mesh size s is set to the tracking distance L, m matches the number of tracking reset from l−N+1 to 1 that is performed until the beam array region passes through the mesh of interest (k, l). When m=l−N+1, the mesh of interest is located at the right end of the (N×N) beam array region. When m=l, the mesh of interest is located at the left end.
n indicates the number of beam irradiation from 0 to m. When the processing mesh size s is set to the tracking distance L, n matches the tracking reset number from 0 to m.

In the first tracking control (tracking cycle), a tracking reset has not yet been performed, so that the tracking reset number is zero. In the second tracking control, a tracking reset has been performed once, so that the tracking reset number is 1.
PSF(n, m, k−i, l−j) indicates a heat spread function.

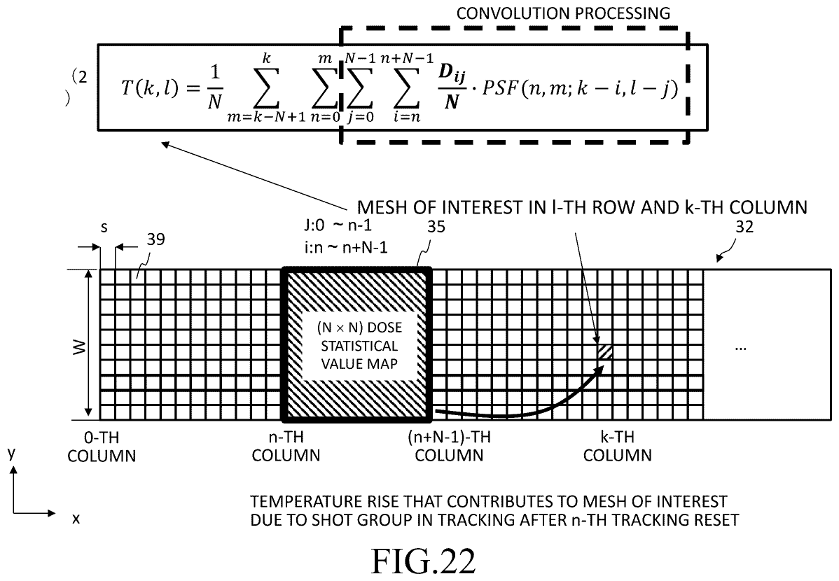

FIG. 22 is a diagram for explaining a part of the effective temperature calculation equation in Embodiment 1. In FIG. 22, a portion surrounded by the dotted line in Equation (2) shows a calculation portion of the convolution process. In the calculation portion of the convolution process in Equation (2), a convolution process is performed to calculate a temperature rise due to heat that is caused by beam irradiation to each mesh region in a rectangular region 35 with the same size as a beam array region formed by N×N processing meshes 39 and that affects a mesh region of interest with an index (k, l). The rectangular region 35 is used in which the left end of the rectangular region 35 corresponds to the n-th column of the processing mesh 39 and the right end corresponds to the (n+N−1)-th column of the processing mesh 39. Therefore, within the rectangular region 35, N×N processing meshes 39 corresponding to the n-th to (n+N−1)-th columns in the x direction and the 0-th to (N−1)-th rows in the y direction are arranged.

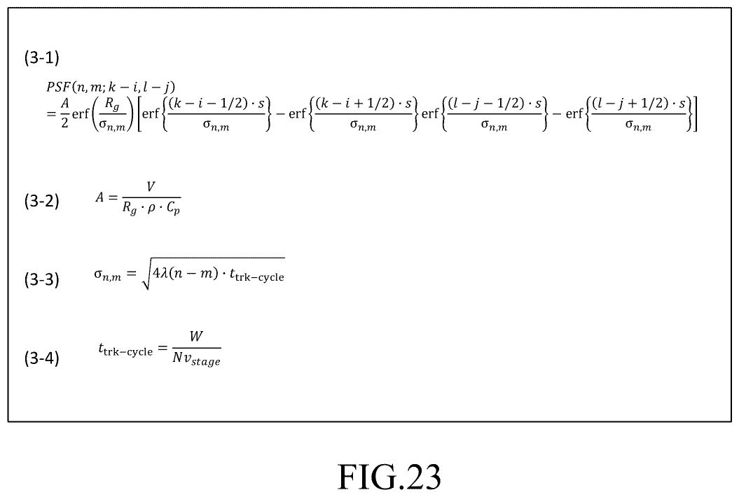

FIG. 23 is a diagram for explaining an example of calculation equation for the heat spread function in Embodiment 1. The heat spread function PSF(n, m, k−i, l−j) is defined by Equation (3-1) shown in FIG. 23. Equation (3-1) can be obtained by solving the heat conduction equation above under the initial conditions that uniform heat is applied to the volume of the mesh size multiplied by Rg on the substrate surface by beam irradiation, with the boundary conditions of infinity in the XY directions and semi-infinity in the substrate depth direction in the Z direction.

The symbols in the heat spread function PSF(n, m, k−i, l−j) overlapping those in Equation (2) are the same symbols as in Equation (2). The heat spread function PSF(n, m, k−i, l−j) shown in FIG. 23 defines a case where the XY stage 105 moves at a constant speed in a direction (−x direction) opposite to the x direction, which is a writing direction, for example. As shown in FIG. 23, the heat spread function PSF(n, m, k−i, l−j) is defined using the tracking cycle time, which is calculated from the speed v of the XY stage 105.

In Equation (3-1), Rg indicates the range of a 50 kV electron beam in quartz. For example, range Rg=(0.046/ρ)E^{1.75} is used.
ρ indicates the density of the substrate (quartz) (for example, 2.2 g/cm\hat{ }3).
σn,m indicates a function determined by the number of tracking resets (m-n) performed from the n-th to the m-th. The function σn,m is defined in Equation (3-3).
A Function A is defined in Equation (3-2).

In Equation (3-2), V indicates the acceleration voltage of the electron beam.
Cp indicates the specific heat of the substrate (quartz) (for example 0.77 J/g/K).

In Equation (3-3), λ indicates the thermal diffusivity of the substrate (quartz) (for example, 0.0081 cm\hat{ }2/sec).
(m-n) indicates the number of tracking resets performed from the n-th to the m-th.
t_{trk-cycle} indicates the tracking cycle time. The tracking cycle time t_{trk-cycle} is expressed by Equation (3-4).
v_{stage} indicates the stage speed.

Normally, in a multi-beam writing apparatus, the stage speed v_{stage}=(constant) in the stage pass is optimized so that the shots (10 shots in the previous example) end in the time between trackings. Since the tracking distance L (=W/N) is tracked at the stage speed, the tracking cycle time t_{trk-cycle} can be defined by Equation (3-4).

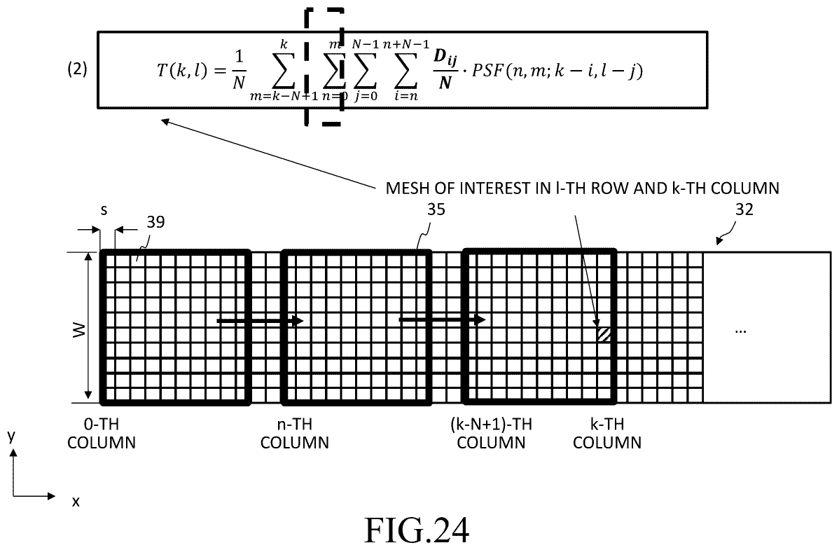

FIG. 24 is a diagram for explaining another part of the effective temperature calculation equation in Embodiment 1. The convolution process described in FIG. 22 is performed until the mesh region of interest with an index (k, l) is included in the rectangular region 35 (n=m) while shifting the position of the rectangular region 35 from the left end (n=0) of the stripe region 32 in the x direction by the size s of the processing mesh 39. This process is indicated by the calculation portion surrounded by the dotted line in Equation (2) shown in FIG. 24. In the example of FIG. 24, a case is shown in which the rectangular region 35 is moved until the mesh region of interest with an index (k, l) is located at the right end of the rectangular region 35. In this state, the left end of the rectangular region 35 is located in the (k−N+1)-th column, and the right end is located in the k-th column.

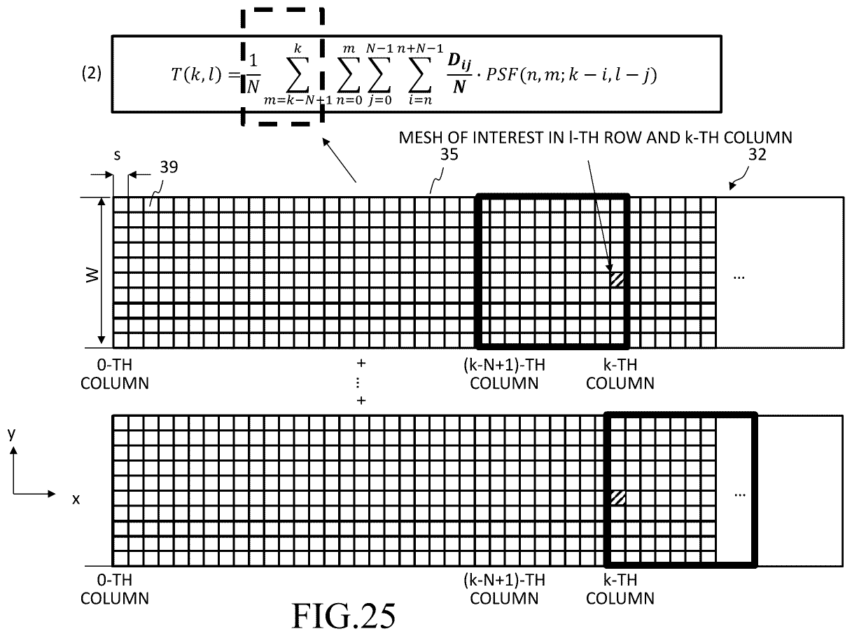

FIG. 25 is a diagram for explaining another part of the effective temperature calculation equation in Embodiment 1.

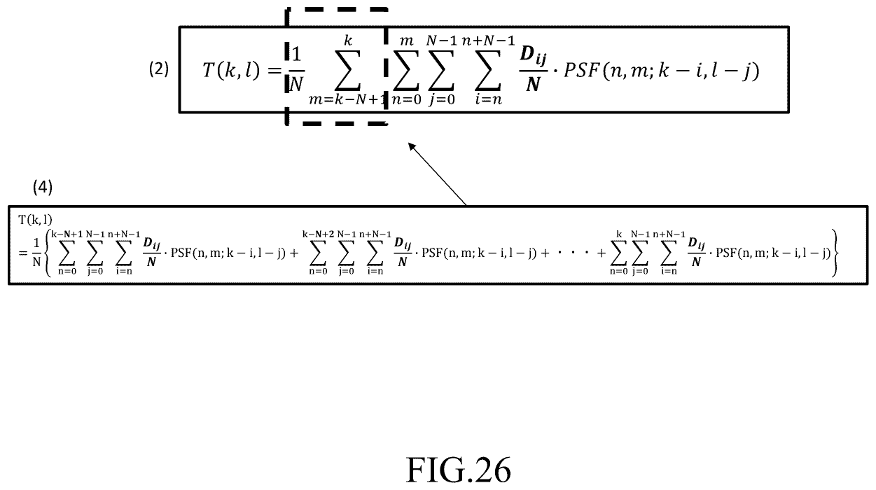

FIG. 26 is a diagram for explaining another part of the effective temperature calculation equation in Embodiment 1. In FIG. 26, the process performed by the calculation portion in FIG. 25 is specifically shown by the equation.

The process shown in FIG. 22 is performed N times from when the mesh region of interest reaches the right end position, which is one end of the rectangular region 35 in the x direction, to when the mesh region of interest reaches the left end position, which is the other end, as shown in FIG. 25. In other words, as shown in Equation (4) in FIG. 26, the process shown in FIG. 24 from n=0 to n=m=k−N+1, the process shown in FIG. 24 from n=0 to n=m=k−N+2, the process shown in FIG. 24 from n=0 to n=m=k-N+3, . . . , the process shown in FIG. 24 from n=0 to n=m=k is performed N times, and the sum of these is calculated. Since N processing meshes 39 are arranged in the x direction in the rectangular region 35, N processes are performed until the mesh region of interest reaches the left end of the rectangular region 35 from the right end. This process is indicated by the calculation portion surrounded by the dotted line in Equation (2) shown in FIG. 25. Then, the statistical value of the results of the N convolution processes is calculated as an effective temperature T(k, l). This process is indicated by the calculation portion surrounded by the dotted line in Equation (2) shown in FIG. 26. In the example of Equation (2), a case is shown in which an average value obtained by dividing the sum of N convolution processes by N is calculated as the effective temperature T(k, l).

In addition, the number of divisions of the rectangular region and the number of calculation processes do not necessarily need to be the same. In other words, the rectangular region may be divided into N portions, and the number of calculation processes may be smaller than N (downsampling). Alternatively, the rectangular region may be divided into N portions, and the N portions may be distributed to a larger number of meshes than N (upsampling).

The effective temperature T(k, l) is not limited to the average value, but may be a maximum value, a minimum value, or a median value of the results of N convolution processes. More preferably, the median value is used. Even more preferably, the average value is used.

The position of the mesh region of interest is changed, and the effective temperature T(i, j) is calculated for each position (i, j) of the processing mesh 39.

As described above, instead of calculating the temperature rise for each shot and each beam, the effective temperature T(i, j) is calculated in units of the processing mesh 39 using the representative dose value Dij of the processing mesh 39. The effective temperature T(i, j) can be calculated for each processing mesh 39, which is sufficiently larger than the pixel 36 that is a unit region of beam irradiation for each shot. Therefore, it is possible to greatly reduce the amount of calculations.

Alternatively, it is also suitable to calculate the effective temperature T(x) using the kernel K(x) as follows. Hereinafter, a specific explanation will be given.

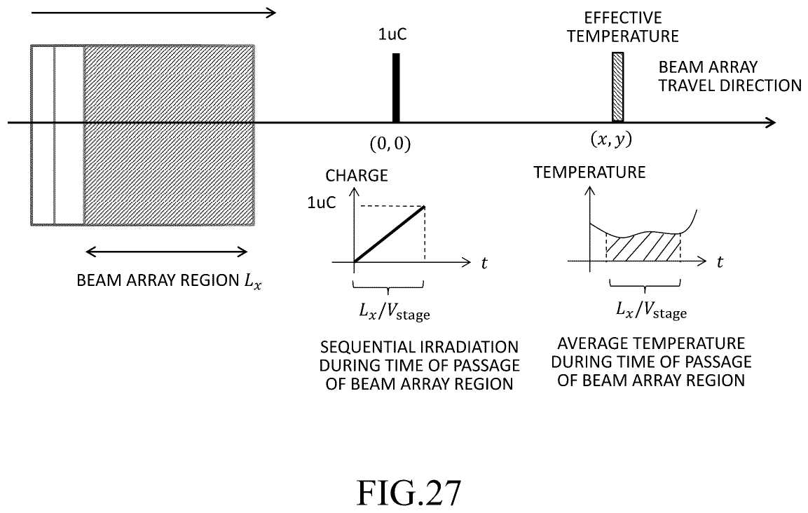

FIG. 27 is a diagram for explaining an example of a virtual model of effective temperature in Embodiment 1. In FIG. 27, when a 1 μC charge is dot-emitted to the position coordinates (0, 0) using the multi-beam writing method, the effective temperature (average temperature while the BAA region passes through an arbitrary position (x, y)) observed at the (x, y) region is calculated to obtain the kernel. In the graph below the position coordinates (0, 0) in FIG. 27, the vertical axis indicates the amount of charge. The horizontal axis indicates time t. In addition, in the graph below the arbitrary position (x, y), the vertical axis indicates temperature. The horizontal axis indicates time t.

As shown in the graph below the position coordinates (0, 0) in FIG. 27, it is assumed that a beam array region with a size Lx in the x direction is continuously linearly irradiated with the charge while moving continuously linearly with a stage speed Vstage. In addition, it is assumed that irradiation starts at the right end of the beam array region and ends at the left end. Based on these two assumptions, the effective temperature at the arbitrary position (x, y) is approximately calculated. The graph below the position coordinates (0, 0) in FIG. 27 shows the state of sequential irradiation as the beam array region passes therethrough. As shown in the graph below the arbitrary position (x, y), a temperature rise occurs at the time (t=Lx/Vstage) when the beam array region is dot-irradiated at the position coordinates (0, 0) and before and after the time. The effective temperature is an average temperature during the time of passage of the beam array region.

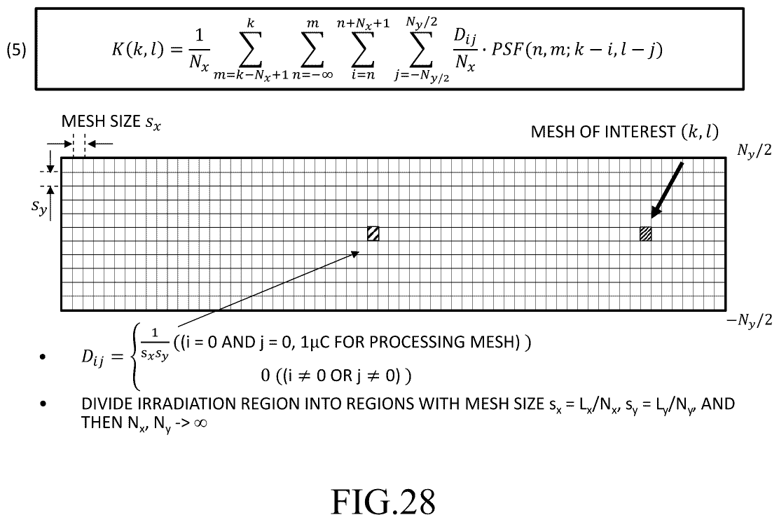

FIG. 28 is a diagram for explaining an example of a kernel derivation process in Embodiment 1. Within the stripe region 32, M processing meshes 39 are arranged in the x direction and Ny processing meshes 39 are arranged in the y direction. Assuming that an intermediate position in the y direction in the stripe region 32 is j=0, processing meshes 39 from −Ny/2 to +Ny/2 are arranged in the y direction in the stripe region 32. In addition, assuming that the position of the center of the stripe region 32 in the x direction is i=0, processing meshes 39 from −∞ to M are arranged in the x direction in the stripe region 32, for example. In Equation (5), among the plurality of processing meshes 39 in the stripe region 32, the coordinate processing mesh 39 in the 1-th row in the y direction and the k-th column in the x direction is shown as a mesh region of interest.

In addition, in FIG. 28, the size sx of the processing mesh 39 in the x direction is a value obtained by dividing the beam array region size Lx in the x direction by the number of meshes Nx in the x direction in the beam array. In addition, the size sy of the processing mesh 39 in the y direction is a value obtained by dividing the beam array region size Ly in the y direction by the number of meshes Ny in the y direction in the beam array.

Here, it is assumed that a processing mesh at a position of i=0 and j=0 is dot-irradiated with a charge of 1 μC. The representative dose value Dij of a processing mesh at a position (0, 0) at this time is Dij=1/(sxsy) as an average value per unit area, and the representative dose value of processing meshes other than i=0 and j=0 is zero. In this case, the effective temperature T(k, l) is defined as the kernel T(k, l). The kernel T(k, l) can be defined by Equation (5) shown in FIG. 28. Since the index setting method has been changed as described above, the integration range on the right side of Equation (5) is converted from the integration range on the right side of Equation (2).

Here, it is assumed that Nx and Ny are infinity ∞. In other words, it is assumed that the size of the processing mesh is infinitesimal.

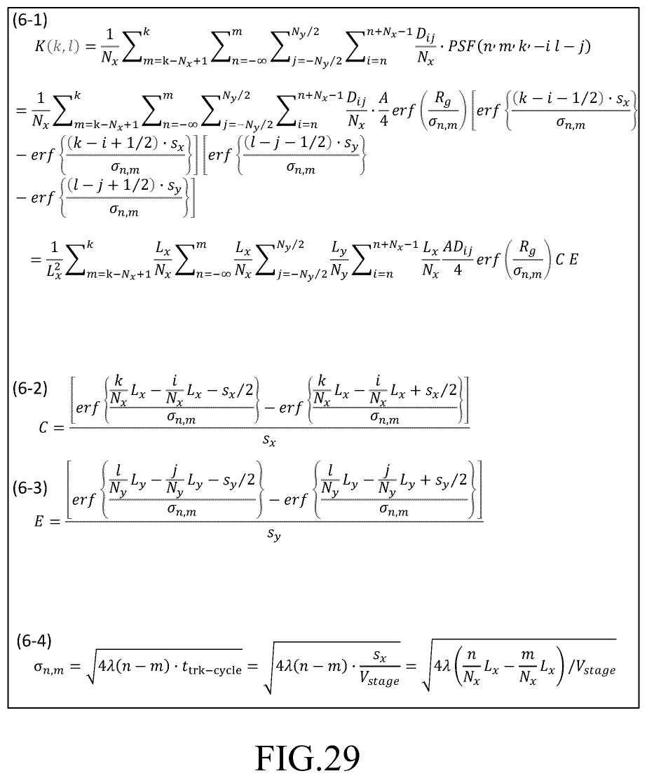

FIG. 29 is a diagram showing another example of the kernel derivation process in Embodiment 1. By making the sizes sx and sy of the processing mesh infinitesimal, Equation (5) can be converted as shown in Equation (6-1). Here, a function C is shown in Equation (6-2). A function E is shown in Equation (6-3). Here, the heat spread function PSF is expressed by the above Equation (3-1) to Equation (3-3). The tracking cycle time t_{trk-cycle} can be defined as a value obtained by dividing the processing mesh size sx in the x direction by the stage speed Vstage. In addition, the processing mesh size sx is a value obtained by dividing the x-direction size Lx of the beam array region by the number of meshes Nx in the x direction in the beam array region. In other words, this means that a virtual tracking distance Lx/Nx is defined. Therefore, the function σn,m in Equation (3-3) can be converted into Equation (6-4).

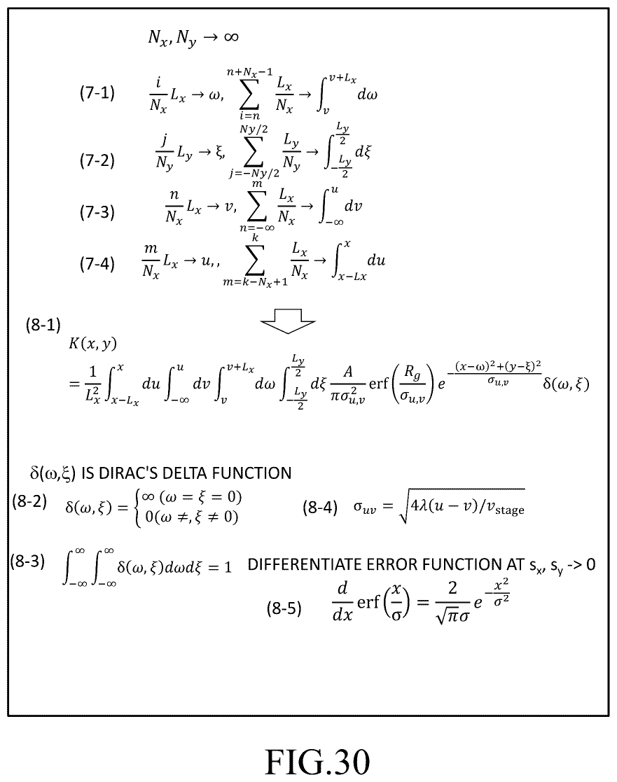

FIG. 30 is a diagram showing another example of the kernel derivation process in Embodiment 1. As described above, it is assumed that the number of meshes Nx and Ny in the processing region overlapping the beam array region are infinite. In other words, it is assumed that the size of the processing mesh 39 is infinitesimal.

Then, in FIG. 30, a value converted by taking Nx to the limit of infinity for an amount obtained by multiplying a value, which is obtained by dividing a reference number i indicating a mesh region in a beam travel direction (x direction) in a processing region with the same size as the beam array region by the number of mesh regions Nx in the beam travel direction in a processing region overlapping the beam array region, by the size Lx of the beam array region in the beam travel direction is defined as an integral variable ω.

In addition, in FIG. 30, a value converted by taking Ny to the limit of infinity for an amount obtained by multiplying a value, which is obtained by dividing a reference number j indicating a mesh region in the y direction in a processing region with the same size as the beam array region by the number of mesh regions Ny in the y direction in a processing region overlapping the beam array region, by the size Ly of the beam array region in the y direction is defined as an integral variable 4.

In addition, a value converted by taking Nx to the limit of infinity for an amount obtained by multiplying a value, which is obtained by dividing a beam irradiation number m (m=k−Nx+1, k−Nx, . . . , k; performed sequentially Nx times until a processing region with a size of Nx×Ny passes through a mesh of interest at coordinates (k, l)) by the number of mesh regions Nx, by the size Lx of the beam array region in the beam travel direction (x direction) is defined as an integral variable u.

In addition, in FIG. 30, a value converted by taking Nx to the limit of infinity for an amount obtained by multiplying a value, which is obtained by dividing a beam irradiation number n performed sequentially (m-th, (m−1)−th, (m−2)-th, . . . ) by the number of mesh regions Nx, by the size Lx of the beam array region in the beam travel direction (x direction) is defined as an integral variable v.

As a result, a convolution processing part that sums Lx/Nx from i=n to n+Nx−1 among the terms on the right side of Equation (6-1) that defines the kernel K(k, l) can be defined as a term component indicating an integral operation for integration from v to v+Lx with the integration variable ω, as shown in Equation (7-1).

In addition, a convolution processing part that sums Ly/Ny from j=−Ly/2 to +Ly/2 among the terms on the right side of Equation (6-1) that defines the kernel K(k, l) can be defined as a term component indicating an integral operation for integration from −Ly/2 to +Ly/2 with the integral variable ξ, as shown in Equation (7-2).

In addition, a convolution processing part that sums Lx/Nx from n=−∞ to m among the terms on the right side of Equation (6-1) that defines the kernel K(k, l), can be defined as a term component indicating an integral operation for integration from −∞ to u with the integral variable v, as shown in Equation (7-3).

In addition, a convolution processing part that sums Lx/Nx from m=k−Nx+1 to k among the terms on the right side of Equation (6-1) that defines the kernel K(k, l) can be defined as a term component indicating an integral operation for integration from x−Lx to x with the integral variable u, as shown in Equation (7-4).

In addition, term components for integration with the integral variables ω and ξ are integral operations indicating the integration of temperature rise at the position (x, y) due to heat generated by the beam emitted at a certain position (ω, ν) in the beam array region when the beam array region is at a certain position v. Therefore, the integration range of ω and ξ is within the beam array region, and ω is from v to v+Lx and ξ is from −Ly/2 to +Ly/2.

Term components for integration with the integral variable v is an integral operation for further integrating the temperature rise at the position (x, y) due to the temperature rise integrated by the above integral operation when the beam array region is at each position from infinity to position u. Therefore, the integration range of v is from −∞ to u.

Term components for integration with the integral variable u is an integral operation for further integrating the temperature rise integrated by the above integral operation when one end of the beam array region is at the position (x, y) to when the other end is at the position (x, y). Therefore, the integration range of u is from x-Lx to x.

Therefore, the kernel K(k, l) can be defined as an integral equation using the integral variables ω, ξ, u, and v. Specifically, the kernel K(k, l) can be defined by the following Equation (8-1) that is a multiplication of a term component indicating an integral operation for integration with the integral variable ω, a term component indicating an integral operation for integration with the integral variable ξ, a term component indicating an integral operation for integration with the integral variable v, a term component indicating an integral operation for integration with the integral variable u, a function A/(πσ_{u,v}²)erf(Rg/(σu,v)e\hat{ }(−((x−ω)²+(y−ξ)²)/σ_{u,v}), and Dirac's delta function δ (ω, ξ).

In addition, the Dirac's delta function δ(ω, ξ) is a function that satisfies Equations (8-2) and (8-3). In addition, the functions σ_{u,v} is defined by Equation (8-4).

In addition, by making the sizes sx and sy of the processing mesh infinitesimal, the differential equation of the error function can be defined by Equation (8-5).

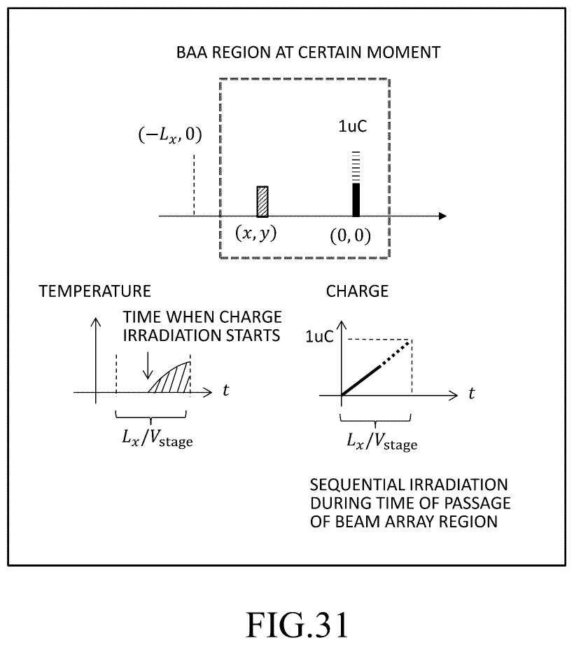

FIG. 31 is a diagram for explaining the kernel in Embodiment 1. A Kernel K(x, y) indicates an average temperature (effective temperature) at an arbitrary position while passing through the beam array region when (x, y)=(0, 0) is continuously irradiated with a charge of 1 μC while passing through the beam array region. A bottom right diagram of FIG. 31 shows how the charge of 1 μC is continuously emitted while passing through the beam array region. The vertical axis indicates the amount of charge, and the horizontal axis indicates time. In such a case, as shown in the upper diagram of FIG. 31, even behind the charge irradiation point of the coordinates (0, 0), a non-zero effective temperature appears at x>−Lx. This is because the heat generated by irradiation at the right end of the beam array region contributes to the heating effect when the inside of the beam array region is irradiated, as shown in the lower left diagram of FIG. 31. That is, the kernel depends on the size Lx of the beam array region.

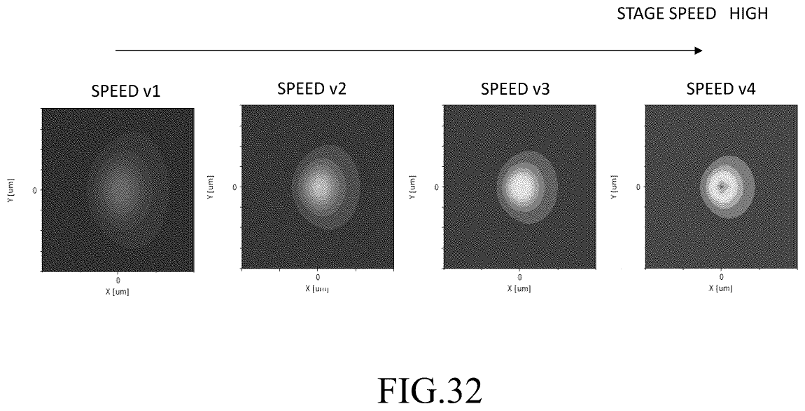

FIG. 32 is a diagram showing an example of the relationship between the stage speed and the kernel in Embodiment 1. The example of FIG. 32 shows an example of four kernels with different stage speeds Vstage (v_{stage}=v1 to v4) when the x-direction size Lx of the beam array is constant. As shown in FIG. 32, kernels with asymmetrical temperature distributions having different heights and shapes for each stage speed are obtained. In the example of FIG. 32, it can be seen that the temperature at the center of the temperature distribution increases as the stage speed increases.

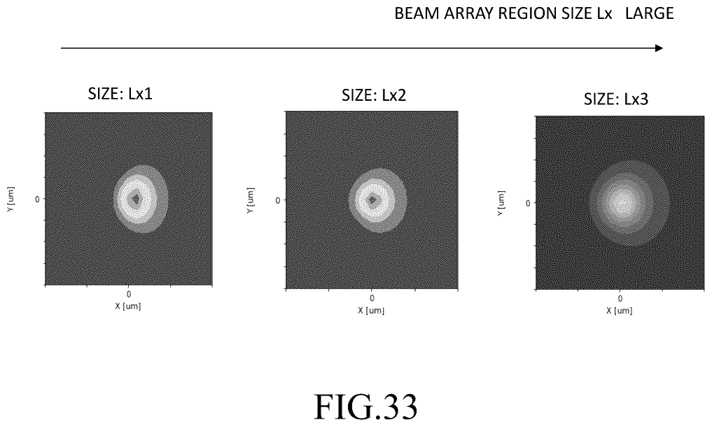

FIG. 33 is a diagram showing an example of the relationship between the movement direction size of the beam array and the kernel in Embodiment 1. The example of FIG. 33 shows an example of three kernels with different x-direction sizes Lx (Lx=Lx1 to Lx3) of the beam array when the stage speed is constant. As shown in FIG. 33, kernels with temperature distributions having different heights and shapes for each x-direction size Lx of the beam array are obtained. In the example of FIG. 25, it can be seen that the temperature at the center of the temperature distribution increases as the x-direction size Lx of the beam array decreases.

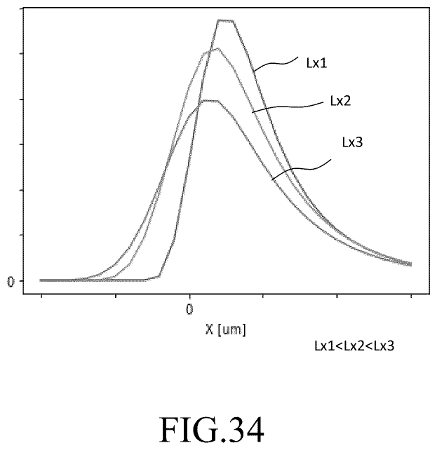

FIG. 34 is a diagram showing another example of the relationship between the movement direction size of the beam array and the kernel in Embodiment 1. FIG. 34 shows an example of the temperature distribution in the x-direction sizes Lx of the three beam arrays in FIG. 33. The vertical axis indicates temperature. The horizontal axis indicates a position in the x direction. As shown in the example of FIG. 34, the shape of the rise and fall of the temperature distribution of the kernel also varies depending on the size Lx of the beam array region.

Therefore, in Embodiment 1, a plurality of kernels are created in advance according to the stage speed and the beam array region size Lx.

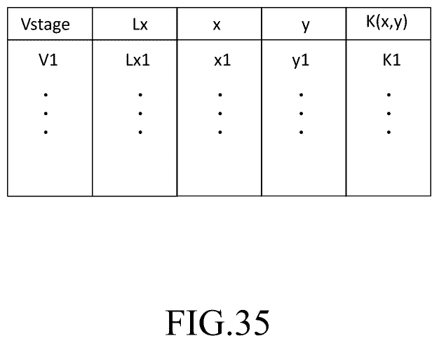

FIG. 35 is a diagram showing an example of a kernel defined as a table in Embodiment 1. In FIG. 35, the kernel K(x, y) is defined as the value of each position within a range larger than the beam array region. This is due to the effect of residual heat after the beam array has passed. For example, when the size Lx of the beam array region is set in the range of about 100 μm (maximum value) to 10 μm (minimum value), it is preferable to calculate the kernel in a region of about ±300 μm in each of the x and y directions.

In the example of FIG. 35, the stage speed Vstage, the size Lx of the beam array region in the x direction (direction opposite to the stage travel direction), the position (x, y), and the kernel value K(x, y) at each position are associated with each other to be defined as a table. The value at each position of the kernel K(x, y) indicates a representative value of the temperature while the beam array region passes through the position under two assumptions of an assumption that a point charge of 1 μC is emitted to the center of the kernel while the beam array region is moving continuously at a constant speed and an assumption that the emission of the point charge starts at one end of the beam array region and ends at the other end.

In addition, the above value is referred to according to the stage speed and the size of the beam array region actually used, and if there is no matching value, a linear interpolation value using the previous and next values may be used.

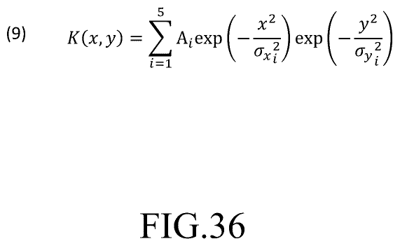

FIG. 36 is a diagram showing an example of a kernel equation defined as a continuous function in Embodiment 1. In the example of FIG. 36, an example of a function that approximates five kernels with different stage speeds by adding up five Gaussian functions that are anisotropic in the x and y directions is shown in Equation (9). In addition, a coefficient Ai is prepared for each stage speed, and linearly interpolated coefficients Ai, cxi, and cyi may be used for speeds between the stage speeds defined in the table. Then, for example, it is preferable to prepare a kernel equation defined as a continuous function for each beam array region size Lx. Alternatively, it is also preferable to prepare a function that approximates a plurality of kernels with different stage speeds and beam array region sizes Lx.

As described above, in Embodiment 1, a plurality of kernels depending on the stage speed and the beam array region size Lx are prepared in advance. The plurality of kernels are stored in the storage device 144.

The acquisition unit 56 acquires the stage speed Vstage and the beam array region size Lx in the current writing process. Specifically, the beam array region size Lx and the stage speed Vstage set when setting the pattern writing conditions (not shown) are acquired. The pattern writing conditions are set by the user through manual input operations. Alternatively, it is also preferable to set a plurality of conditions for each of a plurality of pattern writing condition parameters, including the stage speed Vstage and the beam array region size Lx, on an input screen (not shown) so that the user can select each of the pattern writing condition parameters from among the plurality of conditions that have been set. The beam array region size Lx changes, for example, when a limited number of beams in the beam array that can be emitted by the writing apparatus 100 are used. Specifically, this is a case where only the beam array at the center, which is less affected by aberration, among the beam array is used. Therefore, since the number of beams is reduced, it is possible to improve the writing position accuracy even though the writing time increases.

The kernel determination unit 57 determines a corresponding kernel from among a plurality of kernels according to the acquired (input) stage speed Vstage and beam array region size Lx.

The effective temperature calculation unit 58 receives the speed Vstage of the stage 105 and the size Lx of the beam array region in the x direction, and calculates a representative value of the temperature rise due to heat that is caused by beam irradiation into a processing region with the same size as the beam array region and overlapping the beam array region on the surface of the target object 101 and affects a mesh region of interest (k, l) that is one of the plurality of processing meshes 39, as an effective temperature T(k, l) of the mesh region of interest, using the kernel and representative dose value determined by the speed Vstage of the stage 105 and the size Lx of the beam array region in the x direction. Specifically, the operation is as follows.

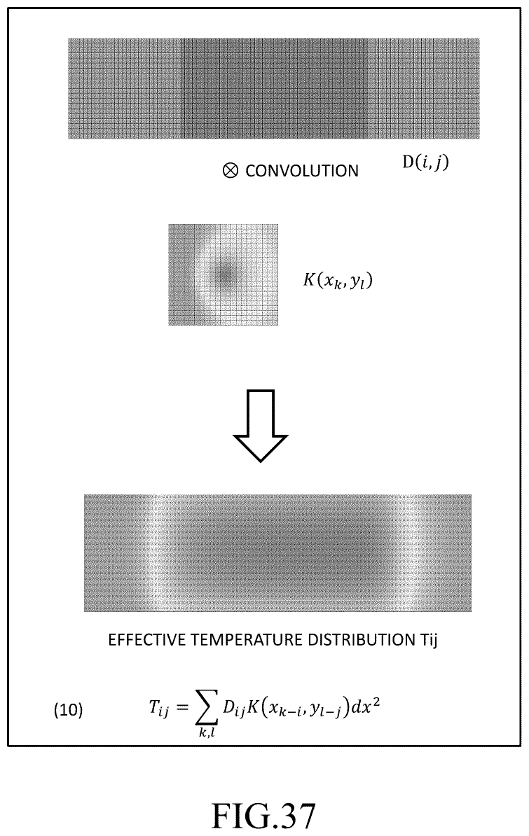

FIG. 37 is a diagram for explaining a method for calculating an effective temperature in Embodiment 1. As shown in FIG. 37, the effective temperature calculation unit 58 performs a convolution process between the dose distribution of the representative dose value Dij and the kernel K(xk, yl). (xk, yl) indicates a position in the kernel. Therefore, it is possible to calculate the effective temperature T(k, l) of the mesh of interest. The effective temperature T(k, l) of the mesh of interest can be defined by Equation (10) showing the convolution process. In the convolution process, the sum of element products between elements with the same position is calculated while shifting the kernel center in the dose distribution. The sum of the element products at the coordinates (k, l) of the kernel center position is the effective temperature T(k, l).

Here, in the above example, a case where the stage 105 moves at a constant speed has been described, but the invention is not limited thereto. The above Equation (10) can be applied even if the stage 105 moves at a variable speed. In such a case, the stage speed distribution is stored in the storage device 144. The effective temperature calculation unit 58 may acquire a stage speed at a position where the kernel center is located and select and use a kernel corresponding to the stage speed at the position where the kernel center is located. In this manner, even in the case of variable speed movement, it is possible to calculate the effective temperature using the kernel described above.

As described above, in Embodiment 1, the effective temperature Tpec(x) before the heating effect correction is calculated.

In the modulation rate calculation step (S114), the modulation rate calculation unit 60 calculates a modulation rate α(x) of the dose that depends on the effective temperature Tpec(x).

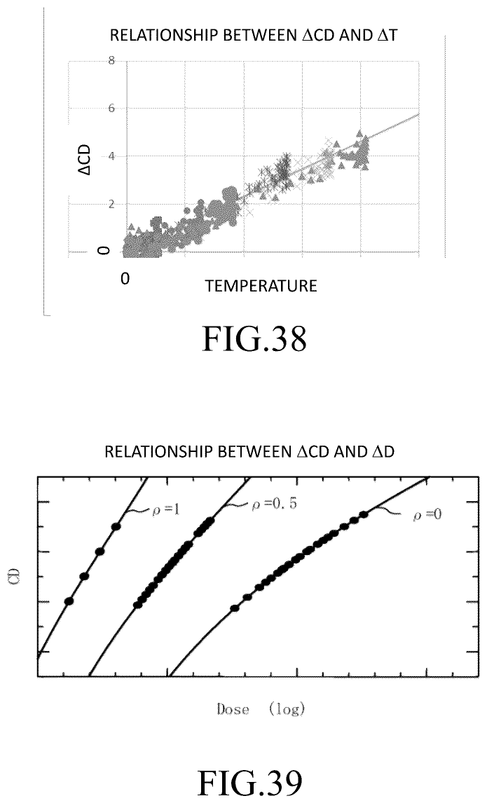

FIG. 38 is a diagram showing an example of the relationship between the line width CD and temperature in Embodiment 1. In FIG. 38, the vertical axis indicates the line width CD (Critical Dimension), and the horizontal axis indicates temperature. As shown in FIG. 38, it can be seen that the deviation of the line width CD increases as the resist temperature increases. A CD variation due to heating effect ΔCD/ΔT [nm/K] has a linear relationship. Since this value differs depending on the type of resist and the type of substrate, this value is obtained by performing experiments on these. Therefore, an approximation equation that approximates the amount of CD change ΔCD per unit temperature ΔT is found out. Such correlation data (1) is input from the outside and stored in the storage device 144.

FIG. 39 is a diagram showing an example of the relationship between the line width CD and the dose in Embodiment 1. In FIG. 39, the vertical axis indicates the line width CD, and the horizontal axis indicates the dose. In the example of FIG. 39, the horizontal axis is plotted using logarithm. As shown in FIG. 39, the line width CD depends on the pattern density, and the line width CD increases as the dose increases. The relationship ΔCD/ΔD between the dose and the CD variation, which depends on each resist/substrate type and pattern density, is obtained by performing experiments. Then, an approximation equation that approximates the amount of CD change ΔCD per unit dose is found out. Such correlation data (2) is input from the outside and stored in the storage device 144.

The modulation rate calculation unit 60 reads out the correlation data (1) and (2) from the storage device 144, and calculates the amount of dose change ΔD per unit temperature ΔT, which depends on the pattern density, as the modulation rate α(x) of the dose, which depends on the effective temperature T. The modulation rate α(x) depending on the pattern density ρ is defined by the following Equation (11).

$$α ( x ) = ( Δ CD / Δ T ) / {( Δ CD / Δ D )}_{ρ} = {( Δ D / Δ T )}_{ρ} \qquad ( 11 )$$

In the correction step (S130), the correction unit 62 (an example of a modulated dose calculation unit) calculates a modulated dose at each position obtained by correcting the dose at each position defined in the dose map using a function that uses an effective temperature distribution map in which the effective temperature is defined for each mesh region, an area density map for each position, and a back scattering coefficient for proximity effect correction. In other words, the correction unit 62 (an example of the modulated dose calculation unit) calculates a heating effect-corrected dose Dtec(x), which is a modulated dose at each position obtained by correcting the heating effect caused by the emission of the multiple beams 20 for the dose at each position defined in the dose map (here, the proximity effect-corrected dose Dpec(x) for each pixel 36), using the function β(x). The heating effect-corrected dose Dtec(x) can be calculated using the above Equation (1-16). The function β(x) is a function that uses the effective temperature distribution map in which the effective temperature Tpec(x) is defined for each mesh region, the area density map in which the area density at each position is defined, the back scattering coefficient η for proximity effect correction, and the modulation rate α(x), as shown in Equation (1-17). A proximity density U(x), which is a value obtained by convolution integral between the area density ρ′ (x) and the distribution function g(x), is used as the area density defined in the area density map.

Then, the correction unit 62 creates a dose map (2) for each stripe region 32 using the calculated heating effect-corrected dose Dtec(x) for each pixel 36 after the heating effect correction. The heating effect-corrected dose Dtec(x) for each pixel 36 is defined as each element of the dose map (2). In this manner, the heating effect-corrected dose Dtec(x) is obtained. In other words, it is possible to set a dose at which it is possible to write a CD dimension from which the correction residuals of the heating effect correction has been eliminated or which has reduced correction residuals of the heating effect correction. The created dose map (2) is stored in the storage device 144.

In the beam irradiation time data generation step (S140), the beam irradiation time data generation unit 72 calculates, for each pixel 36, a beam irradiation time t of an electron beam for making the calculated heating effect-corrected dose Dtec(x) incident on the pixel 36. The beam irradiation time t can be calculated by dividing the heating effect-corrected dose Dtec(x) by the current density J. When the heating effect-corrected dose Dtec(x) is a relative value normalized with the base doses of the beam Db set to 1, the beam irradiation time t can be calculated by dividing a value, which is obtained by multiplying the heating effect-corrected dose Dtec(x) by the base doses of the beam Db, by the current density J.

The beam irradiation time t of each pixel 36 is calculated as a value within the maximum beam irradiation time Ttr that can be irradiated in one shot of the multiple beams 20. The beam irradiation time t of each pixel 36 is converted into gray scale value data of 0 to 1023 gray scale levels, with the maximum beam irradiation time Ttr being, for example, 1023 gray scale level (10 bits). The beam irradiation time data after gradation by gray scale levels is stored in the storage device 142.

In the data processing step (S142), the data processing unit 74 rearranges the beam irradiation time data in a shot order according to the writing sequence, and also rearranges the beam irradiation time data in a data transfer order taking into account the arrangement order of the shift registers of each group.

In the writing step (S144), under the control of the writing control unit 80, the transfer control unit 79 transfers the beam irradiation time data to the deflection control circuit 130 in the shot order. The deflection control circuit 130 outputs a blanking control signal to the blanking aperture array mechanism 204 in the shot order, and also outputs a deflection control signal to the DAC amplifier units 132 and 134 in the shot order.

Then, the writing mechanism 150 writes a pattern on the target object 101 using the multiple beams 20 with the heating effect-corrected dose Dtec(x) (modulated dose).

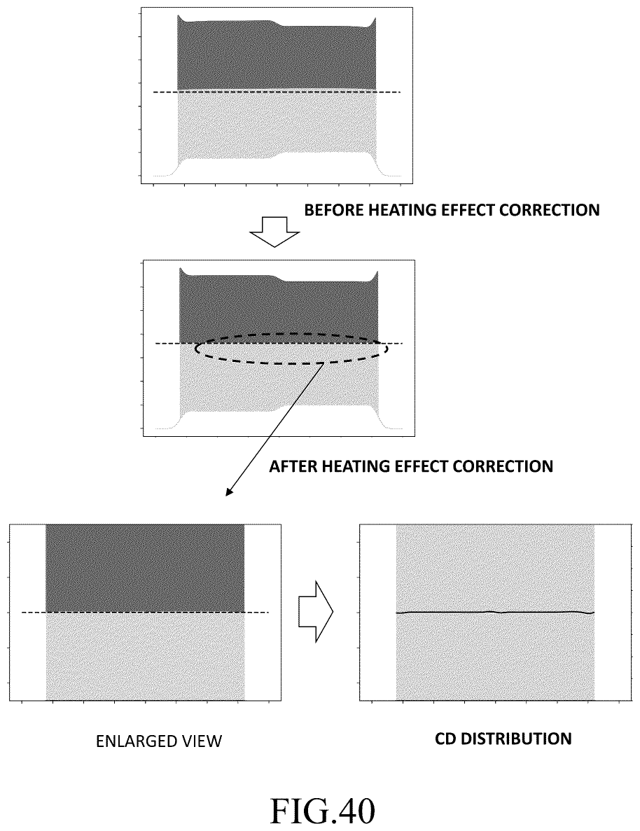

FIG. 40 is a diagram showing an example of accumulated energy distribution and an example of CD distribution after heating effect correction in Embodiment 1. In the accumulated energy distribution shown in FIG. 40, portions above and below the ISO-FOCAL dose level are shown in different colors. Therefore, the boundary between the two colors indicates the ISO-FOCAL dose level. By the dose modulation using the function β(x) in Embodiment 1, in the accumulated energy distribution after the heating effect correction, the ISO-FOCAL dose level can be made to approximately match the resolution threshold value, as shown in FIG. 40. Therefore, as shown in the CD distribution, the distribution of the line width CD of the pattern approximately matches the design value.

As described above, according to Embodiment 1, when correcting resist heating in multi-beam writing, the correction residuals can be reduced.

### Embodiment 2

In Embodiment 1, a configuration has been described in which the function β(x) is calculated while ignoring the term of the difference ΔD² in Equation (1-14), but the invention is not limited thereto. In Embodiment 2, a configuration using a function β′(x) including such a term will be described. Hereinafter, the contents other than those specifically noted are the same as those in Embodiment 1.

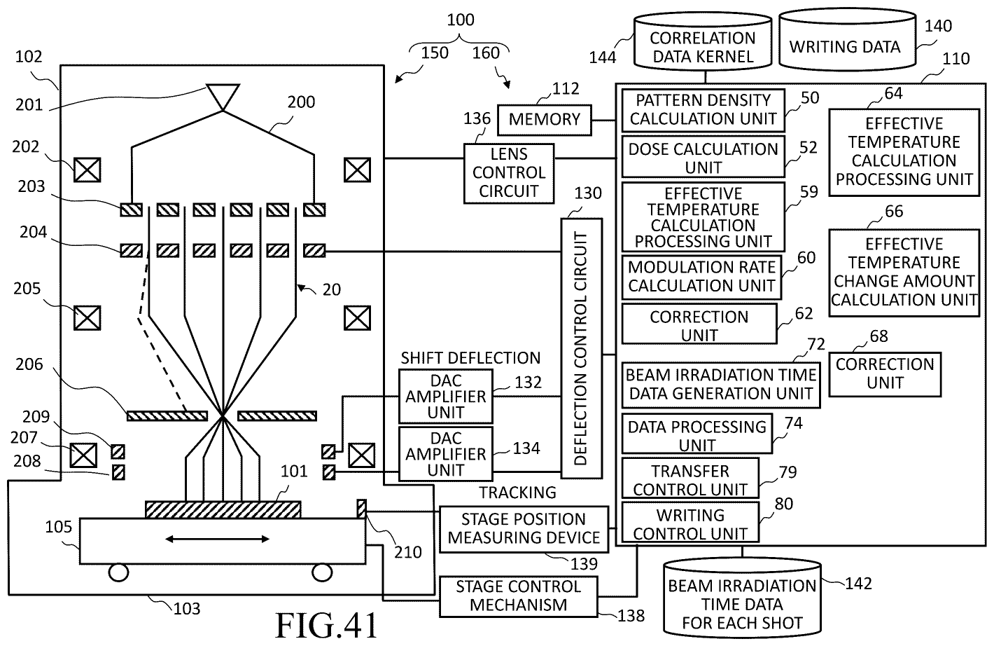

FIG. 41 is a conceptual diagram showing the configuration of a writing apparatus according to Embodiment 2. FIG. 41 is the same as FIG. 1 except that an effective temperature calculation processing unit 64, an effective temperature change amount calculation unit 66, and a correction unit 68 are further added in the control calculator 110.

Each “˜unit”, such as the pattern density calculation unit 50, the dose calculation unit 52, the effective temperature calculation processing unit 59, the modulation rate calculation unit 60, the correction unit 62, the effective temperature calculation processing unit 64, the effective temperature change amount calculation unit 66, the correction unit 68, the beam irradiation time data generation unit 72, the data processing unit 74, the transfer control unit 79, and the writing control unit 80, has a processing circuit. Examples of such a processing circuit include an electrical circuit, a computer, a processor, a circuit board, a quantum circuit, or a semiconductor device. For each “˜unit”, a common processing circuit (the same processing circuit) may be used or different processing circuits (separate processing circuits) may be used. Information input and output to and from the pattern density calculation unit 50, the dose calculation unit 52, the effective temperature calculation processing unit 59, the modulation rate calculation unit 60, the correction unit 62, the effective temperature calculation processing unit 64, the effective temperature change amount calculation unit 66, the correction unit 68, the beam irradiation time data generation unit 72, the data processing unit 74, the transfer control unit 79, and the writing control unit 80 and information being calculated are stored in the memory 112 each time.

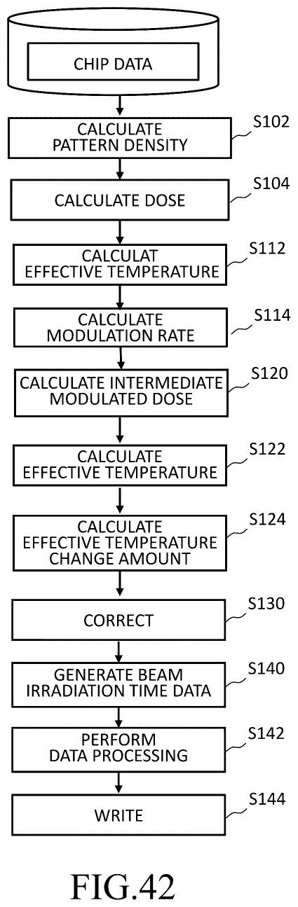

FIG. 42 is a flowchart showing an example of main steps of a writing method according to Embodiment 2. FIG. 42 is the same as FIG. 18 except that an intermediate modulated dose calculation step (S120), an effective temperature calculation step (S122), and an effective temperature change amount calculation step (S124) are added between the modulation rate calculation step (S114) and the correction step (S130).

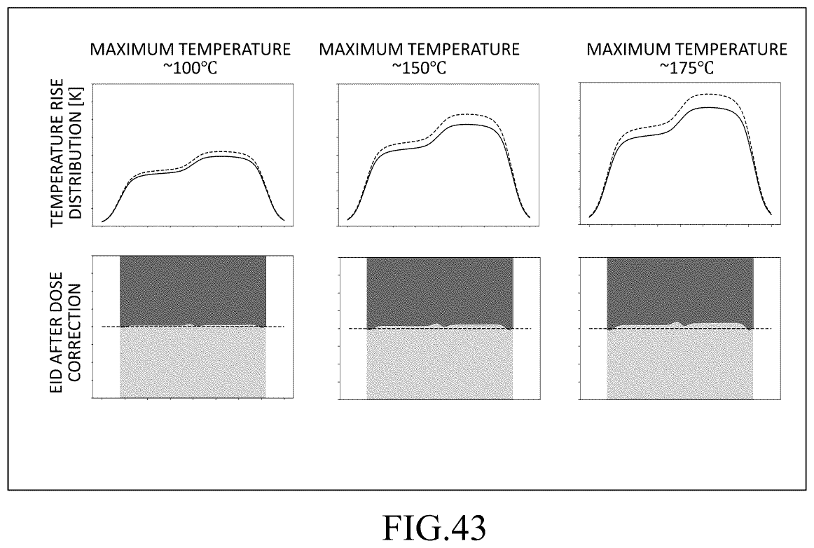

FIG. 43 is a diagram showing an example of the accumulated energy distribution when performing heating effect correction with the maximum value of the effective temperature variable using the method according to Embodiment 1. The example in FIG. 43 shows an accumulated energy distribution when the effective temperature Tpec is up to 100° C., an accumulated energy distribution when the effective temperature Tpec is up to 150° C., and an accumulated energy distribution when the effective temperature Tpec is up to 175° C. The two-color boundary between the accumulated energy distributions indicates an ISO-focal dose level. In addition, in FIG. 43, a graph of the effective temperature distribution is shown above the graph of the accumulated energy distribution for each maximum temperature. In the effective temperature distribution for each maximum temperature, the effective temperature Tpec calculated under conditions before the heating effect correction is shown by the solid line. The effective temperature Ttec calculated under conditions after the heating effect correction is shown by the dotted line. It can be seen that the deviation of the ISO-focal dose level from the resolution threshold value increases as the maximum temperature increases. This is thought to be due to an increase in the amount of change ΔT (=Ttec−Tpec) in effective temperature before and after the heating effect correction.

Therefore, in Embodiment 2, a correction is performed taking into account the amount of change ΔT in the effective temperature.

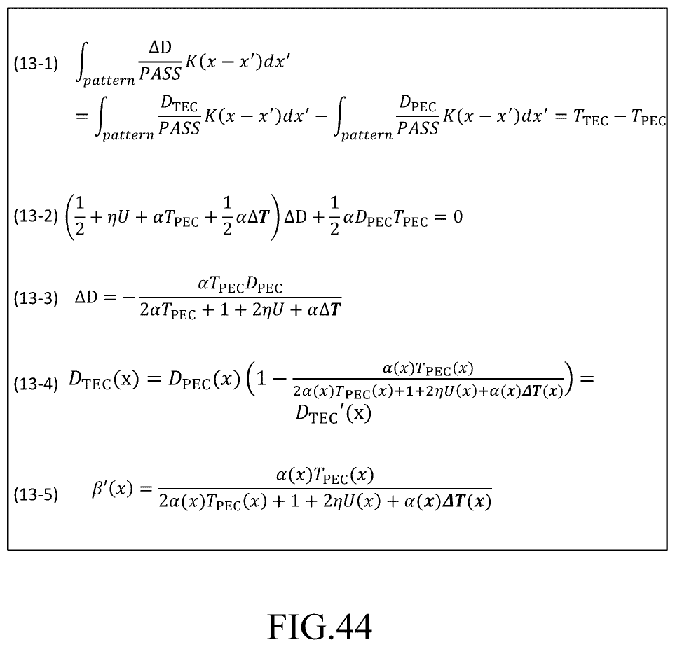

FIG. 44 is a diagram for explaining an example of a process of deriving a correction term in Embodiment 2. An integral part of the first term, which is a term of the difference ΔD² in Equation (1-14), can be converted into Equation (13-1) by substituting the difference ΔD=Dtec−Dpec, which is obtained by modifying Equation (1-12). Therefore, the integral part of the first term, which is a term of the difference ΔD² in Equation (1-14), is Ttec(x)−Tpec(x) (=ΔT(x)).

Therefore, Equation (1-14) can be converted into Equation (13-2).

Here, the difference ΔD is small, and furthermore, due to the characteristics of the heating effect in multiple beams, the change is also small within the range of integration and is accordingly negligibly approximated and removed from the integration. Thereafter, by rearranging Equation (13-1) for ΔD, Equation (13-1) can be converted into Equation (13-3).

By substituting the calculated ΔD into Equation (13-2) for conversion, Dtec′(x) (=Dtec(x)) can be converted into Equation (13-4).

Therefore, the function β′(x), which is a correction term in Embodiment 2, is defined using the effective temperature Tpec(x), the proximity density U(x), the back scattering coefficient η, the modulation rate α(x), and the amount of change ΔT(x) in effective temperature. In other words, the function β′(x) in Embodiment 2 further includes the amount of change ΔT(x) in effective temperature ΔT(x) before and after correction of the dose at each position, in addition to the parameters used in the function β(x) in Embodiment 1, as a correction term. In addition, in other words, the function β′(x) in Embodiment 2 further includes the amount of change ΔT(x) in effective temperature before and after the heating effect correction, in addition to the parameters used in the function β(x) in Embodiment 1, as a correction term. The function β′(x) can be defined by Equation (13-5).

By performing writing with a beam of a heating effect-corrected dose Dtec′(x) obtained by correcting the proximity effect-corrected dose Dpec(x) using this function β′(x), the correction residuals of the pattern line width CD due to the heating effect correction can be eliminated or reduced even if the maximum effective temperature Tpec(x) becomes high. Hereinafter, a writing method that uses the function β′(x) to perform correction will be described.

The contents of each step up to the modulation rate calculation step (S114) are the same as those in Embodiment 1. In the effective temperature calculation step (S112), the effective temperature calculation processing unit 59 (first effective temperature calculation circuit) calculates the effective temperature Tpec(x) (first effective temperature) using the dose before the heating effect correction, as described above.

In the intermediate modulated dose calculation step (S120), the correction unit 62 (an example of a modulated dose calculation unit) calculates the heating effect-corrected dose Dtec(x), which is a modulated dose at each position obtained by correcting the heating effect caused by the emission of the multiple beams 20 for the dose at each position defined in the dose map (here, the proximity effect-corrected dose Dpec(x) for each pixel 36), using the function β(x) shown in Equation (1-17) used in Embodiment 1. The heating effect-corrected dose Dtec(x) can be calculated using the above Equation (1-16). In Embodiment 2, the calculated heating effect-corrected dose Dtec(x) is the intermediate modulated dose.

In the effective temperature calculation step (S122), the effective temperature calculation processing unit 64 (second effective temperature calculation circuit) calculates the effective temperature Ttec(x) (second effective temperature) using the modulated dose corrected using the effective temperature Tpec(x) (first effective temperature). In other words, the effective temperature calculation processing unit 64 (second effective temperature calculation circuit) calculates the effective temperature Ttec(x) (second effective temperature) after the heating effect correction using the intermediate modulated dose Dtec(x) obtained by correcting the heating effect using the effective temperature Tpec(x) (first effective temperature). The internal configuration of the effective temperature calculation processing unit 64 may be the same as the internal configuration of the effective temperature calculation processing unit 59 shown in FIG. 19. In addition, the method for calculating the effective temperature Ttec(x) after the heating effect correction is the same as the method for calculating the above-described effective temperature Tpec(x) before the heating effect correction. However, the intermediate modulated dose Dtec(x) is used to calculate the representative dose value Dij.

In the effective temperature change amount calculation step (S124), the effective temperature change amount calculation unit 66 calculates the amount of change ΔT(x) (=Ttec(x)−Tpec(x)) between the effective temperature Tpec(x) and the effective temperature Ttec(x).

In the correction step (S130), the correction unit 68 (another example of the modulated dose calculation unit) calculates a heating effect-corrected dose Dtec′(x), which is a modulated dose at each position obtained by correcting the heating effect caused by the emission of the multiple beams 20 for the dose at each position defined in the dose map (here, the proximity effect-corrected dose Dpec(x) for each pixel 36), using the function β′(x) in Embodiment 2. The heating effect-corrected dose Dtec′(x) can be calculated using the above Equation (13-4). The function β′(x) is a function that uses the effective temperature distribution map in which the effective temperature Tpec(x) is defined for each mesh region, the area density map in which the proximity density U(x) at each position is defined, the back scattering coefficient I for proximity effect correction, the modulation rate α(x), and the effective temperature change amount ΔT(x), as shown in Equation (13-5).

Then, the correction unit 68 creates a dose map (2) for each stripe region 32 using the calculated heating effect-corrected dose Dtec′(x) for each pixel 36 after the heating effect correction. The heating effect-corrected dose Dtec′(x) for each pixel 36 is defined as each element of the dose map (2). In this manner, the heating effect-corrected dose Dtec′(x) is obtained. In other words, it is possible to set a dose at which it is possible to write a CD dimension from which the correction residuals of the heating effect correction has been eliminated or which has reduced correction residuals of the heating effect correction. The created dose map (2) is stored in the storage device 144.

The contents after the beam irradiation time data generation step (S140) are the same as those in Embodiment 1. However, the beam irradiation time t can be calculated by dividing the heating effect-corrected dose Dtec′(x) by the current density J. When the heating effect-corrected dose Dtec′(x) is a relative value normalized with the base doses of the beam Db set to 1, the beam irradiation time t can be calculated by dividing a value, which is obtained by multiplying the heating effect-corrected dose Dtec′(x) by the base doses of the beam Db, by the current density J.

Then, the writing mechanism 150 writes a pattern on the target object 101 using the multiple beams 20 with the heating effect-corrected dose Dtec′(x) (modulated dose).

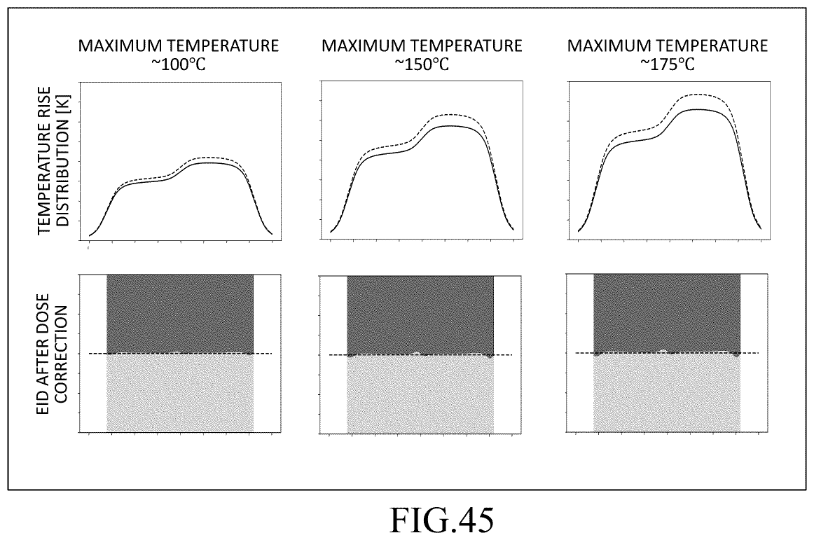

FIG. 45 is a diagram showing an example of the accumulated energy distribution when performing heating effect correction with the maximum value of the effective temperature in Embodiment 2 variable. The example in FIG. 45 shows an accumulated energy distribution when the effective temperature Tpec is up to 100° C., an accumulated energy distribution when the effective temperature Tpec is up to 150° C., and an accumulated energy distribution when the effective temperature Tpec is up to 175° C. The two-color boundary between the accumulated energy distributions indicates an ISO-focal dose level. In addition, the effective temperature distribution is shown above the accumulated energy distribution for each maximum temperature. In the effective temperature distribution for each maximum temperature, the effective temperature Tpec calculated under conditions before the heating effect correction is shown by the solid line. The effective temperature Ttec calculated under conditions after the heating effect correction is shown by the dotted line. In Embodiment 2, since the amount of change ΔT(x) in effective temperature is included as a correction term in the function β′(x), the amount of deviation of the ISO-focal dose level from the resolution threshold value can be suppressed to a small value even if the maximum temperature increases.

The embodiments have been described above with reference to specific examples. However, the invention is not limited to these specific examples. The invention is not limited to the multi-charged particle beam writing apparatus and the multi-charged particle beam writing method, but can be applied to a charged particle beam writing apparatus and a charged particle beam writing method using raster beams.

In addition, the functions of the processes described in Embodiments 1 and 2 may be executed by a computer. Then, a program for causing a computer to execute such functions of the processes may be stored, for example, in a non-transitory, tangible, and computer-readable storage medium, such as a magnetic disk drive.

In addition, the description of parts that are not directly required for the description of the invention, such as the apparatus configuration or the control method, is omitted. However, the required apparatus configuration, control method, and the like can be appropriately selected and used. For example, although the description of the control unit configuration for controlling the writing apparatus 100 is omitted, it is needless to say that the required control unit configuration can be appropriately selected and used.

In addition, all charged particle beam writing apparatuses, charged particle beam writing methods, and programs (or non-transitory computer-readable storage media storing a program) that include the elements of the invention and that can be appropriately modified by those skilled in the art are included in the scope of the invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A charged particle beam writing apparatus, comprising:
a dose map creation circuit configured to create a dose map defining a dose incident on a position concerned for each of a plurality of positions in each of a plurality of stripe regions obtained by dividing a writing region on a surface of a target object irradiated with a charged particle beam in a first direction;
an effective temperature calculation circuit configured to calculate, for each of a plurality of mesh regions obtained by dividing each stripe region in the first direction and a second direction, corresponding to a stage movement direction, linearly independent of the first direction, a representative value of a temperature rise while a beam array region irradiated with multiple beams is passing through a mesh region of interest as a mesh region concerned, among temperature rises due to heat caused by beam irradiations onto the surface of the target object and affecting the mesh region of interest, as an effective temperature of the mesh region of interest;
a modulated dose calculation circuit configured to calculate a modulated dose at each position obtained by correcting a dose at each position defined in the dose map using a function using an effective temperature distribution map defining the effective temperature for each mesh region, an area density map for each position, and a back scattering coefficient for proximity effect correction; and
a writing mechanism configured to write a pattern on the target object using a charged particle beam with the modulated dose.

2. The apparatus according to claim 1, wherein
the function further includes an amount of change in effective temperature before and after correction of the dose at each position as a correction term.

3. The apparatus according to claim 2, wherein
the effective temperature calculation circuit serves as a first effective temperature calculation circuit, and calculates a first effective temperature as the effective temperature using a dose before correction, further comprising:
a second effective temperature calculation circuit configured to calculate a second effective temperature using the modulated dose obtained by correction using the first effective temperature; and
an effective temperature change amount calculation circuit configured to calculate an amount of change between the first effective temperature and the second effective temperature.

4. The apparatus according to claim 1, wherein
a dose in which a proximity effect is corrected is used as each dose defined in the dose map.

5. The apparatus according to claim 1, wherein
a value obtained by convolution integral between an area density and a distribution function is used as an area density defined in the area density map.

6. A charged particle beam writing method, comprising:
creating a dose map defining a dose incident on a position concerned for each of a plurality of positions in each of a plurality of stripe regions obtained by dividing a writing region on a surface of a target object irradiated with a charged particle beam in a first direction;
calculating, for each of a plurality of mesh regions obtained by dividing each stripe region in the first direction and a second direction, corresponding to a stage movement direction, linearly independent of the first direction, a representative value of a temperature rise while a beam array region irradiated with multiple beams is passing through a mesh region of interest as a mesh region concerned, among temperature rises due to heat caused by beam irradiations onto the surface of the target object and affecting the mesh region of interest, as an effective temperature of the mesh region of interest;
calculating a modulated dose at each position obtained by correcting a dose at each position defined in the dose map using a function using an effective temperature distribution map defining the effective temperature for each mesh region, an area density map for each position, and a back scattering coefficient for proximity effect correction; and
writing a pattern on the target object using a charged particle beam with the modulated dose.

7. A non-transitory computer-readable storage medium storing a program for causing a computer to execute processing comprising:
creating a dose map defining a dose incident on a position concerned for each of a plurality of positions in each of a plurality of stripe regions obtained by dividing a writing region on a target object surface irradiated with a charged particle beam in a first direction;
calculating, for each of a plurality of mesh regions obtained by dividing each stripe region in the first direction and a second direction, corresponding to a stage movement direction, linearly independent of the first direction, a representative value of a temperature rise while a beam array region irradiated with multiple beams is passing through a mesh region of interest as a mesh region concerned, among temperature rises due to heat caused by beam irradiations onto the surface of the target object and affecting the mesh region of interest, as an effective temperature of the mesh region of interest;
storing an effective temperature distribution map defining the effective temperature for each mesh region in a storage device;
reading out the effective temperature distribution map from the storage device and calculating a modulated dose at each position obtained by correcting a dose at each position defined in the dose map using a function using the effective temperature distribution map, an area density map for each position, and a back scattering coefficient for proximity effect correction; and
writing a pattern on the target object using a charged particle beam with the modulated dose.
